(19) United States
(12) Patent Application Publication
(10) Pub. No.: US 2026/0179698 A1
(43) Pub. Date: Jun. 25, 2026

(54) SEMICONDUCTOR MEMORY DEVICE

(71) Applicant: Kioxia Corporation, Tokyo (JP)

(72) Inventors: Koji KATO, Yokohama Kanagawa (JP); Xu LI, Yokohama Kanagawa (JP)

(73) Assignee: Kioxia Corporation, Tokyo (JP)

(21) Appl. No.: 19/318,403

(22) Filed: Sep. 4, 2025

(30) Foreign Application Priority Data
Dec. 24, 2024 (JP) 2024-227384

(51) Int. Cl. G11C 16/34; G11C 16/08; G11C 16/10; G11C 16/30

(52) U.S. Cl. CPC G11C 16/3459; G11C 16/08; G11C 16/102; G11C 16/30

(57) ABSTRACT

According to one embodiment, a semiconductor memory device includes a first word line, a second word line, a first memory cell connected to the first word line, a second memory cell connected to the second word line, and a control circuit configured to perform a data write operation to the first memory cell and the second memory cell. In the write operation, a plurality of program loops each including a program operation and a verify operation are sequentially executed. In the verify operation for a first memory cell, the control circuit applies a second voltage to a first word line in a case of applying a first voltage to a second word line, and then applies a third voltage according to a write state to the first word line to change a voltage level of the second voltage according to the progress of the program loops.

### CROSS-REFERENCE TO RELATED APPLICATIONS

This application is based upon and claims the benefit of priority from Japanese Patent Application No. 2024-227384, filed Dec. 24, 2024, the entire contents of which are incorporated herein by reference.

### FIELD

Embodiments described herein relate generally to a semiconductor memory device.

### BACKGROUND

A NAND flash memory is known as a semiconductor memory device. In the NAND flash memory, a program operation for increasing a threshold voltage in a case where data is written to a memory cell transistor and a verify operation for confirming the threshold voltage are executed.

### BRIEF DESCRIPTION OF DRAWINGS

FIG. 1 is a block diagram illustrating an example of a configuration of a memory system including a semiconductor memory device according to a first embodiment.

FIG. 2 is a circuit diagram illustrating an example of a circuit configuration of a memory cell array included in the semiconductor memory device according to the first embodiment.

FIG. 3 is a plan view illustrating an example of a planar layout of the memory cell array included in the semiconductor memory device according to the first embodiment.

FIG. 4 is a plan view illustrating an example of a planar layout in a memory area of the memory cell array included in the semiconductor memory device according to the first embodiment.

FIG. 5 is a cross-sectional view taken along the line V-V of FIG. 4, illustrating an example of a cross-sectional structure in the memory area of the memory cell array included in the semiconductor memory device according to the first embodiment.

FIG. 6 is a cross-sectional view taken along the line VI-VI of FIG. 5, illustrating an example of a cross-sectional structure of a memory pillar included in the semiconductor memory device according to the first embodiment.

FIG. 7 is a circuit diagram illustrating an example of a circuit configuration of a row decoder module included in the semiconductor memory device according to the first embodiment.

FIG. 8 is a circuit diagram illustrating an example of a circuit configuration of a driver module included in the semiconductor memory device according to the first embodiment.

FIG. 9 is a conceptual diagram illustrating an example of a data storage method of the semiconductor memory device according to the first embodiment.

FIG. 10 is a table illustrating an example of settings of program loops in a write operation of the semiconductor memory device according to the first embodiment.

FIG. 11 is a timing chart illustrating an example of a voltage of a selected word line in the write operation of the semiconductor memory device according to the first embodiment.

FIG. 12 is a timing chart illustrating, in more detail, an example of the voltage of the selected word line in the write operation of the semiconductor memory device according to the first embodiment.

FIG. 13 is a timing chart illustrating, in more detail, an example of the voltage of the selected word line in the write operation of the semiconductor memory device according to the first embodiment.

FIG. 14 is a diagram for describing an example of a method of controlling the voltage applied to the selected word line in the write operation of the semiconductor memory device according to the first embodiment.

FIG. 15 is a timing chart illustrating an example of a voltage of a selected word line in a write operation of a semiconductor memory device according to a second embodiment.

FIG. 16 is a diagram for describing an example of a method of controlling the voltage applied to the selected word line in the write operation of the semiconductor memory device according to the second embodiment.

FIG. 17 is a timing chart illustrating an example of a voltage of a selected word line in a write operation of a semiconductor memory device according to a third embodiment.

FIG. 18 is a diagram for describing an example of a method of controlling the voltage applied to the selected word line in the write operation of the semiconductor memory device according to the third embodiment.

FIG. 19 is a timing chart illustrating an example of a voltage of a selected word line in a write operation of a semiconductor memory device according to a fourth embodiment.

FIG. 20 is a diagram for describing an example of a method of controlling the voltage applied to the selected word line in the write operation of the semiconductor memory device according to the fourth embodiment.

FIG. 21 is a diagram for describing an example of a method of controlling a voltage applied to a selected word line in a write operation of a semiconductor memory device according to a fifth embodiment.

FIG. 22 is a diagram for describing an example of a method of controlling a voltage applied to a selected word line in a write operation of a semiconductor memory device according to a sixth embodiment.

FIG. 23 is a block diagram illustrating an example of a configuration of a memory system including a semiconductor memory device according to a seventh embodiment.

FIG. 24 is a circuit diagram illustrating an example of a circuit configuration of a driver module included in the semiconductor memory device according to the seventh embodiment.

FIG. 25 is a diagram for describing an example of a method of controlling a verify initial time period in a write operation of the semiconductor memory device according to the seventh embodiment.

FIG. 26 is a diagram for describing an example of a method of controlling an underkick voltage in a write operation of a semiconductor memory device according to a first modification of the seventh embodiment.

FIG. 27 is a diagram for describing an example of a method of controlling a stable time of a voltage of a bit line in a write operation of a semiconductor memory device according to a second modification of the seventh embodiment.

### DETAILED DESCRIPTION

In general, according to one embodiment, a semiconductor memory device includes a first word line, a second word line, a first memory cell connected to the first word line, a second memory cell connected to the second word line, and a control circuit configured to perform a data write operation to the first memory cell and the second memory cell. In the write operation, a plurality of program loops each including a program operation and a verify operation are sequentially executed. In the verify operation for a first memory cell, the control circuit applies a second voltage to a first word line in a case of applying a first voltage to a second word line, and then applies a third voltage according to a write state to the first word line to change a voltage level of the second voltage according to the progress of the program loops.

Hereinafter, embodiments will be described with reference to the drawings. The drawings are schematic, and dimensions and ratios of the drawings are not necessarily the same as actual ones. In the following description, components having substantially the same functions and configurations are denoted by the same reference numerals. In a case where components having similar configurations are particularly distinguished from each other, different letters or numbers may be added to the end of the same reference numeral.

In the following description, a state that a first component is “connected” to another second component includes a state that the first component is connected to the second component indirectly via an intermediate component that is always or selectively conductive, or directly without an intermediate component.

### 1. First Embodiment

A semiconductor memory device according to a first embodiment will be described.

### 1.1 Configuration

### 1.1.1 Configuration of Memory System

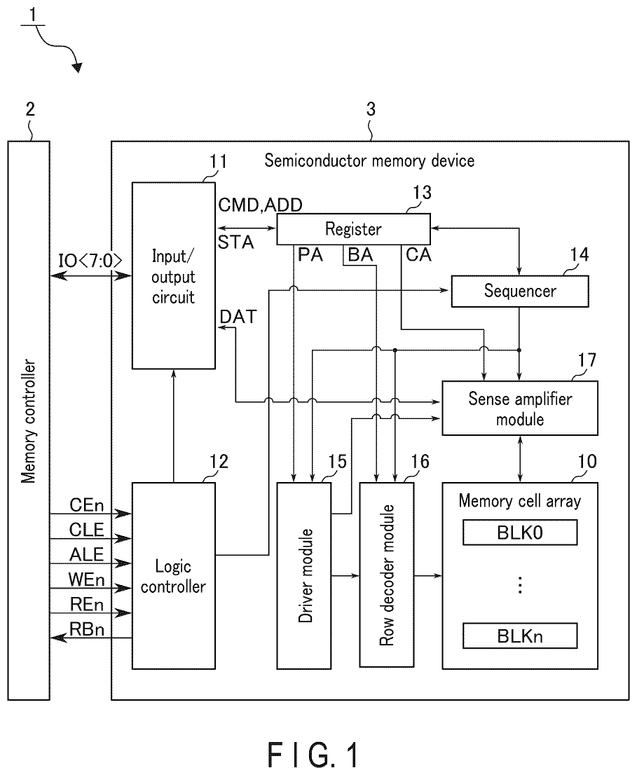

A configuration of a memory system including the semiconductor memory device according to the first embodiment will be described with reference to FIG. 1. FIG. 1 is a block diagram illustrating an example of a configuration of a memory system including a semiconductor memory device according to a first embodiment.

The memory system 1 is a memory device configured to be connected to an external host device (not illustrated). The memory system 1 is, for example, a solid state drive (SSD), a universal flash storage (UFS) device, a universal serial bus (USB) memory, a multi-media card (MMC), or an SD™ card. The memory system 1 includes a memory controller 2 and a semiconductor memory device 3.

The memory controller 2 is a device that controls the semiconductor memory device 3. The memory controller 2 is, for example, a system on a chip (SoC). The memory controller 2 controls the semiconductor memory device 3 based on a request from the external host device. Specifically, the memory controller 2 writes, to the semiconductor memory device 3, data requested to be written by the external host device. In addition, the memory controller 2 reads, from the semiconductor memory device 3, data requested to be read from the external host device and outputs the data to the external host device.

The semiconductor memory device 3 is a memory that stores data in a volatile or non-volatile manner. Hereinafter, a case where the semiconductor memory device 3 is a NAND flash memory will be described.

Communication between the memory controller 2 and the semiconductor memory device 3 conforms to, for example, a single data rate (SDR) interface, a toggle double data rate (DDR) interface, or an open NAND flash interface (ONFI). Signals including signals IO<7:0>, CEn, CLE, ALE, WEn, REn, and RBn are exchanged between the memory controller 2 and the semiconductor memory device 3, for example.

### 1.1.2 Configuration of Semiconductor Memory Device

The internal configuration of the semiconductor memory device 3 will be described with reference to FIG. 1. The semiconductor memory device 3 includes, for example, a memory cell array 10, an input/output circuit 11, a logic controller 12, a register 13, a sequencer 14, a driver module 15, a row decoder module 16, and a sense amplifier module 17.

The memory cell array 10 is a collection of a set of memory cell transistors and components connected to the memory cell transistors. The memory cell array 10 includes a plurality of blocks BLK0 to BLKn (n is an integer equal to or greater than one). The block BLK is a collection of the memory cell transistors capable of storing data in a non-volatile manner. The block BLK is used, for example, as an erase unit in a case where data stored in the memory cell transistor is erased. A plurality of bit lines and a plurality of word lines are provided in the memory cell array 10. Each of the memory cell transistors is associated with, for example, a combination of a bit line and a word line. A detailed configuration of the memory cell array 10 will be described later.

The input/output circuit 11 is an interface circuit that controls transmission and reception of signals IO<7:0> to and from the memory controller 2. The signal IO<7:0> is an 8-bit signal. The signal IO<7:0> includes, for example, data DAT, command CMD, address information ADD, and status information STA. The input/output circuit 11 inputs and outputs the data DAT between the sense amplifier module 17 and the memory controller 2. The input/output circuit 11 outputs, to the register 13, each of the command CMD and the address information ADD transferred from the memory controller 2. The input/output circuit 11 outputs, to the memory controller 2, the status information STA transferred from the register 13.

The logic controller 12 is an interface circuit that controls reception of the signals CEn, CLE, ALE, WEn, and REn input from the memory controller 2 and transmission of the signal RBn to the memory controller 2. The logic controller 12 controls each of the input/output circuit 11 and the sequencer 14 based on the signals CEn, CLE, ALE, WEn, and REn. For example, the logic controller 12 controls the sequencer 14 based on the signal CEn to enable the semiconductor memory device 3. The logic controller 12 notifies the input/output circuit 11 that the input/output signals received by the input/output circuit 11 are the command CMD and the address information ADD based on the signals CLE and ALE, respectively. The logic controller 12 orders the input/output circuit 11 to input and output the signals IO<7:0> based on the signals WEn and REn. In addition, the logic controller 12 outputs, to the memory controller 2, the signal REn indicating whether the semiconductor memory device 3 is in a ready state (a state that accepts commands from the outside) or a busy state (a state that does not accept commands from the outside).

The register 13 temporarily stores the command CMD, the address information ADD, and the status information STA. The command CMD includes, for example, a command for causing the sequencer 14 to execute a read operation, a write operation, an erase operation, and the like. The address information ADD includes, for example, a block address BA, a page address PA, and a column address CA. For example, the block address BA, the page address PA, and the column address CA are used to select a block BLK, a word line, and a bit line, respectively. The status information STA is used to notify the memory controller 2 whether the operation has been normally ended. The status information STA is updated based on the control of the sequencer 14 and transferred to the input/output circuit 11.

The sequencer 14 controls the entire operation of the semiconductor memory device 3. For example, the sequencer 14 controls the driver module 15, the row decoder module 16, the sense amplifier module 17, and the like based on the command CMD stored in the register 13. The sequencer 14 executes, for example, the read operation, the write operation, and the erase operation.

The driver module 15 generates voltages of different magnitudes used in the read operation, the write operation, the erase operation, and the like. The driver module 15 supplies the generated voltages to the row decoder module 16, the sense amplifier module 17, and the like. In addition, the driver module 15 applies the generated voltages to the signal line corresponding to the word line selected based on the page address PA stored in the register 13, for example.

The row decoder module 16 selects a corresponding block BLK in the memory cell array 10 based on the block address BA stored in the register 13, for example. The row decoder module 16 transfers the voltage of the signal line applied by the driver module 15 to the selected word line in the selected block BLK, for example.

The sense amplifier module 17 includes a sense amplifier unit SAU that can determine data based on the voltage of an associated bit line, a latch circuit that temporarily stores data, and the like. In the write operation, the sense amplifier module 17 applies a predetermined voltage to each bit line according to write data DAT received from the input/output circuit 11. In addition, the sense amplifier module 17 determines data stored in the memory cell transistor based on the magnitude of the voltage of the bit line in the read operation. Thereafter, the sense amplifier module 17 transfers a determination result as read data DAT to the input/output circuit 11.

### 1.1.3 Circuit Configuration of Memory Cell Array

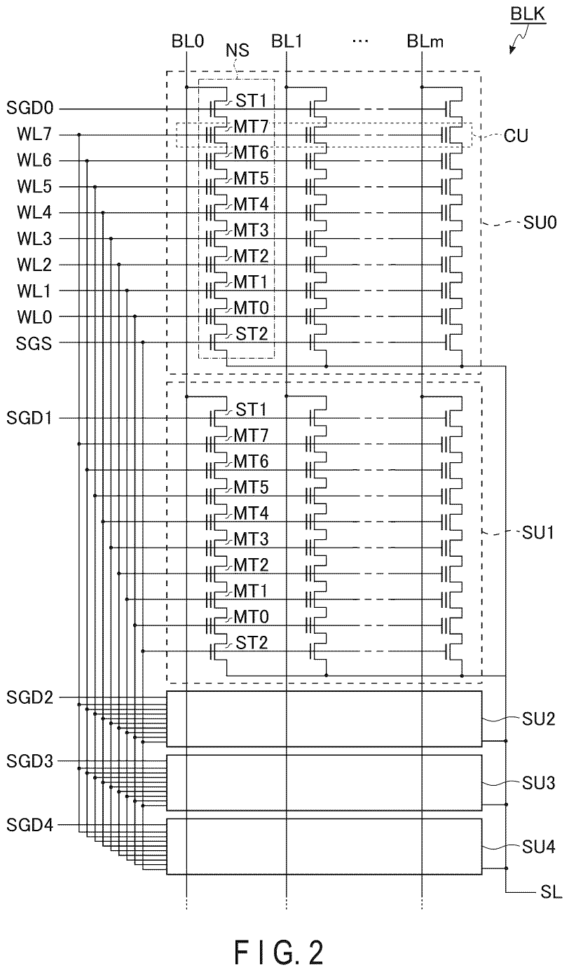

A circuit configuration of the memory cell array 10 will be described with reference to FIG. 2. FIG. 2 is a circuit diagram illustrating an example of a circuit configuration of the memory cell array 10. FIG. 2 illustrates a circuit configuration of the block BLK included in the memory cell array 10 as an example of the circuit configuration of the memory cell array 10. The other blocks BLK also have the same configuration as in FIG. 2.

The block BLK includes, for example, five string units SU0 to SU4. Hereinafter, in a case where the string units SU0 to SU4 are not distinguished, they are simply referred to as string units SU. The string unit SU is, for example, a set of a plurality of NAND strings NS to be collectively selected in the write operation or the read operation. The string unit SU includes the NAND strings NS respectively associated with bit lines BL0 to BLm (m is an integer equal to or greater than one). Hereinafter, in a case where the bit lines BL0 to BLm are not distinguished, they are simply referred to as bit lines BL. The NAND string NS is a set of a plurality of memory cell transistors connected in series. Each NAND string NS includes, for example, memory cell transistors MT0 to MT7 and select transistors ST1 and ST2. Hereinafter, in a case where the memory cell transistors MT0 to MT7 are not distinguished, they are simply referred to as memory cell transistors MT. The memory cell transistor MT stores data in a non-volatile manner. The memory cell transistor MT includes a control gate and a charge storage film. The select transistors ST1 and ST2 are switching elements. Each of the select transistors ST1 and ST2 is used to select the string unit SU during various operations.

In the NAND string NS, the memory cell transistors MT0 to MT7 are connected in series. A drain of the select transistor ST1 is connected to an associated bit line BL. A source of the select transistor ST1 is connected to one end of the memory cell transistors MT0 to MT7 connected in series. A drain of the select transistor ST2 is connected to the other end of the memory cell transistors MT0 to MT7 connected in series. A source of the select transistor ST2 is connected to a source line SL.

In a same block BLK, the control gates of the memory cell transistors MT0 to MT7 are commonly connected to the word lines WL0 to WL7, respectively. Hereinafter, in a case where the word lines WL0 to WL7 are not distinguished, they are simply referred to as word lines WL. Gates of the select transistors ST1 in the string units SU0 to SU4 are commonly connected to select gate lines SGD0 to SGD4, respectively. Hereinafter, in a case where the select gate lines SGD0 to SGD4 are not distinguished, they are simply referred to as select gate lines SGD. Gates of the select transistors ST2 included in the same block BLK are commonly connected to a select gate line SGS.

In the circuit configuration of the memory cell array 10 described above, the bit line BL is shared by, for example, the NAND strings NS to which the same column address CA is allocated in the string units SU. The source line SL is shared by the blocks BLK, for example.

A set of the memory cell transistors MT connected to a common word line WL in the string unit SU is referred to as, for example, a cell unit CU. The block BLK includes a plurality of cell units CU. Data stored in the cell unit CU including the memory cell transistors MT each storing 1-bit data according to a threshold voltage corresponds to one-page data. The cell unit CU can store two-page data or more based on the number of bits of data stored in the memory cell transistor MT. Hereinafter, a case where the memory cell transistor MT is a triple level cell (TLC) that stores 3-bit data will be described.

Further, the circuit configuration of the memory cell array 10 is not limited to the configuration described above. For example, the number of string units SU included in the block BLK and the number of memory cell transistors MT and select transistors ST1 and ST2 included in the NAND string NS may be arbitrary numbers. Hereinafter, the memory cell transistor MT is also referred to as a “memory cell MT”.

### 1.1.4 Structure of Memory Cell Array

The structure of the memory cell array 10 will be described. In the following description, the extending direction of the word lines WL is defined to as an X direction. The extending direction of the bit lines BL is defined as a Y direction. In a case viewed from the source line SL side, a direction in which the interconnect layers corresponding to the select gate lines SGD and SGS and the word lines WL are stacked is defined as a Z direction or an upward direction. A direction opposite to the upward direction is defined as a downward direction. In the plan view, hatching is appropriately added in order to enhance the visibility of the drawing. The hatching added to the plan view is not necessarily associated with a material or a characteristic of the component to which the hatching is added.

### 1.1.4.1 Planar Layout of Memory Cell Array

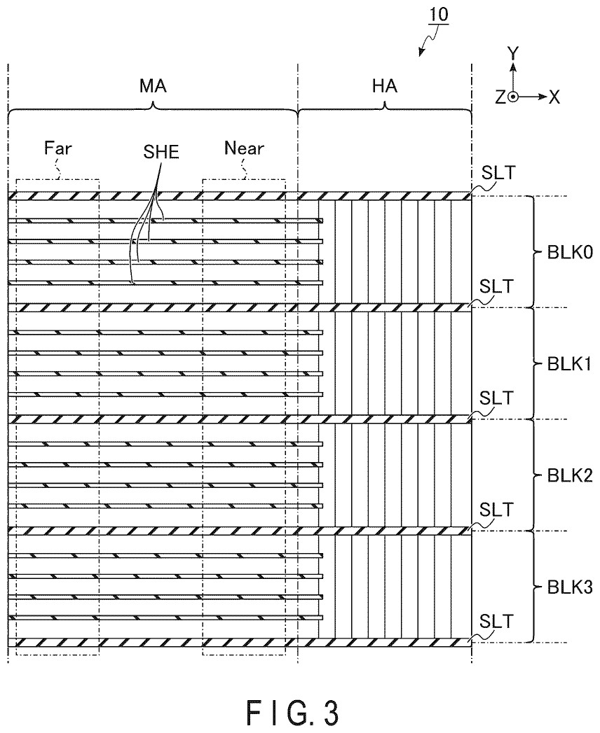

FIG. 3 is a plan view illustrating an example of a planar layout of the memory cell array 10. In FIG. 3, regions corresponding to the four blocks BLK0 to BLK3 are illustrated. The sequence numbers at the ends for distinguishing the blocks BLK are assigned in ascending order from the upper side of the drawing. In the memory cell array 10, for example, the layout illustrated in FIG. 3 is repeatedly arranged in the Y direction. As illustrated in FIG. 3, the memory cell array 10 includes a stacked interconnect formed by stacking a plurality of interconnect layers (for example, the word lines WL0 to WL7 and the select gate lines SGS and SGD) apart from each other in the Z direction, a plurality of members SLT, and a plurality of members SHE. The planar layout of the memory cell array 10 is divided into, for example, a memory area MA and a hookup area HA in the X direction.

The memory area MA is an area that includes the NAND strings NS and is used to store data. The hookup area HA is an area used for connection between each interconnect layer of the stacked interconnect and the row decoder module 16. For example, each interconnect layer of the stacked interconnect is formed in a stepped shape so as to be connected to the row decoder module 16 from the bit line BL side without interfering with other interconnect layers in the hookup area HA.

Each of the members SLT extends along the X direction and the members SLT are arranged in the Y direction. Each member SLT crosses the memory area MA and the hookup area HA in the X direction in the boundary region between the adjacent blocks BLK. In other words, each of the regions divided by the members SLT corresponds to one block BLK in the memory cell array 10. Each member SLT has, for example, a structure in which an insulator and a plate-like contact are embedded. Each member SLT divides the stacked interconnect adjacent to each other with the member SLT interposed therebetween.

The members SHE are arranged in the memory area MA. Each of the members SHE is provided to cross the memory area MA in the X direction and the members SHE are arranged in the Y direction. An end of each member SHE on the right side of the drawing is included in the hookup area HA. For example, in the memory area MA, the four members SHE are arranged between the members SLT adjacent to each other in the Y direction. Each of the areas divided by the members SLT and SHE of the memory area MA corresponds to one string unit SU in the memory cell array 10. Each member SHE has, for example, a structure in which an insulator is embedded. Each member SHE divides the adjacent select gate lines SGD via the member SHE.

The planar layout of the memory cell array 10 is not limited to the layout described above. For example, the number of members SHE arranged between the adjacent members SLT can be designed to be any number. The number of string units SU formed between the adjacent members SLT can be changed based on the number of members SHE arranged between the adjacent members SLT.

In the semiconductor memory device 3, the word lines WL0 to WL7 extend in the X direction, and a voltage is applied from the row decoder module 16 via a contact (not illustrated) connected in the hookup area HA. In this case, in a portion of the word line WL that is included in the memory area MA and far from the hookup area HA, the influence of the delay of the interconnect may not be ignored.

In the present specification, “delay” indicates a length of an RC delay time indicating a time period from when a voltage is applied to the interconnect until the voltage of the interconnect rises or falls to a target value. Further, in the following description, a portion, which is far from the hookup area HA, of the word line WLk (k is an integer satisfying 0≤k≤7) that is included in the memory area MA is referred to as a “far end of the word line WLk”, and is indicated to as “Far” in the drawings. A portion, which is close to the hookup area HA, of the word line WLk that is included in the memory area MA is referred to as a “near end of the word line WLk”, and is indicated as “Near” in the drawings. The timing at which the voltage reaches the target value may be different between the near end and the far end of the word line WLk.

### 1.1.4.2 Planar Layout of Memory Area

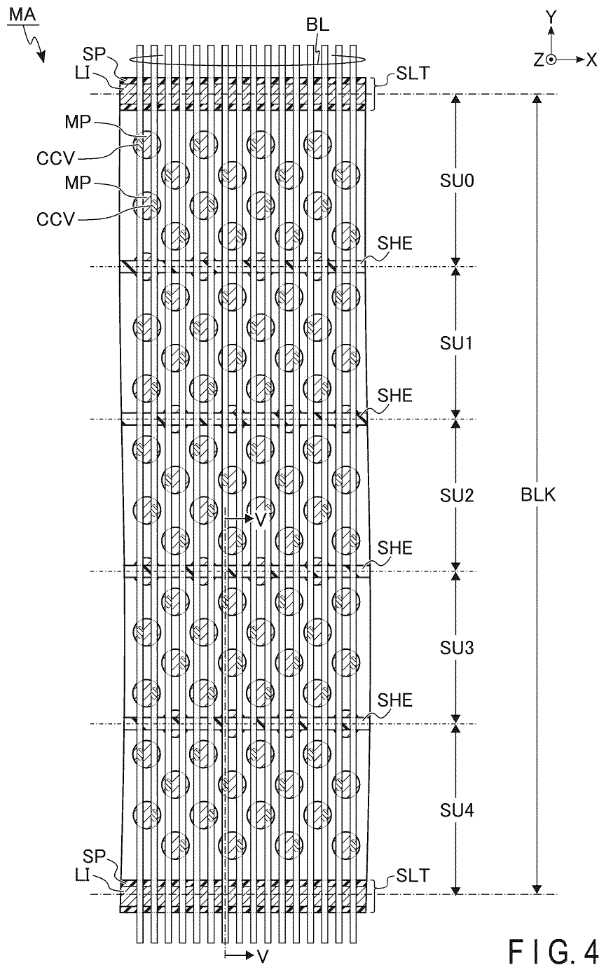

FIG. 4 is a plan view illustrating an example of a planar layout in the memory area MA of the memory cell array 10. As illustrated in FIG. 4, in the memory area MA, the memory cell array 10 includes a plurality of memory pillars MP, a plurality of contacts CCV, and a plurality of bit lines BL. Each member SLT includes a contact LI and a spacer SP.

Each of the memory pillars MP functions as a NAND string NS, for example. The memory pillars MP are arranged in a staggered manner of 24 rows in the Y direction, for example, in a region between two adjacent members SLT. In the example illustrated in FIG. 4, the members SHE overlap the memory pillars MP of the fifth row, the 10th row, the 15th row, and the 20th row, respectively, from the upper side of the paper surface.

Each of the bit lines BL extends in the Y direction and the bit lines BL are arranged in the X direction. Each bit line BL is arranged so as to overlap at least one memory pillar MP for each string unit SU. In the example illustrated in FIG. 4, two bit lines BL are arranged to overlap each memory pillar MP. In a case where more than one bit lines BL overlap each memory pillar MP, one bit line BL of the bit lines BL and the corresponding one memory pillar MP are electrically connected via the contact CCV. In a case where only one bit line BL overlaps each memory pillar MP, the bit line BL and the corresponding memory pillar MP are electrically connected via the contact CCV.

For example, the contact CCV between the memory pillar MP in contact with the member SHE and the corresponding bit line BL is omitted. In other words, the contact CCV between the memory pillar MP and the bit line BL in contact with the two different select gate lines SGD is omitted. The number and arrangement of the memory pillars MP, the members SHE, and the like between the adjacent members SLT are not limited to the configuration illustrated in FIG. 4, and can be appropriately changed. For example, the number of bit lines BL overlapping each memory pillar MP can be designed to any number.

The contact LI is a conductor extending in the XZ plane. The lower surface of the contact LI is in contact with the source line SL (not illustrated). The spacer SP is an insulator provided on a side surface of the contact LI. In other words, the spacer SP is provided in contact with the contact LI so as to sandwich the contact LI in the Y direction.

### 1.1.4.3 Cross-Sectional Structure of Memory Area

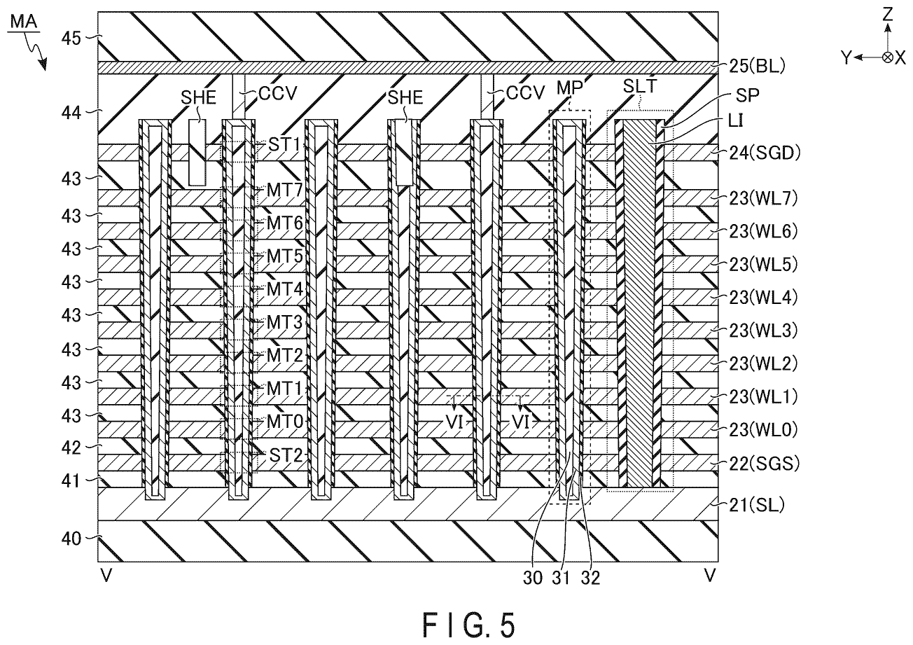

FIG. 5 is a cross-sectional view taken along the line V-V of FIG. 4, illustrating an example of a cross-sectional structure in the memory area MA of the memory cell array 10. As illustrated in FIG. 5, the memory cell array 10 further includes interconnect layers 21 to 25 and insulating layers 40 to 45.

As illustrated in FIG. 5, the insulating layer 40, the interconnect layer 21, the insulating layer 41, the interconnect layer 22, and the insulating layer 42 are stacked in this order. The interconnect layer 21 is formed in, for example, a plate shape extending along the X direction on the XY plane. The interconnect layer 21 is used as the source line SL. The interconnect layer 21 includes, for example, phosphorus-doped silicon. The interconnect layer 22 is formed in, for example, a plate shape extending along the X direction on the XY plane. The interconnect layer 22 is used as the select gate line SGS. The interconnect layer 22 includes, for example, tungsten. The insulating layer 40 includes, for example, interconnects and pads (not illustrated) for connecting the semiconductor memory device 3 to an external device.

The interconnect layers 23 and the insulating layers 43 are alternately stacked one by one above the insulating layer 42. In the example illustrated in FIG. 5, eight interconnect layers 23 and eight insulating layers 43 are alternately stacked one by one. Each interconnect layer 23 is formed in, for example, a plate shape extending along the X direction on the XY plane. The interconnect layers 23 are used as the word lines WL0 to WL7 in order from the wiring layer 22 side. Each interconnect layer 23 includes, for example, tungsten.

The interconnect layer 24 and the insulating layer 44 are stacked in this order above the uppermost insulating layer 43. The interconnect layer 24 is formed in, for example, a plate shape extending along the X direction on the XY plane. The interconnect layer 24 is used as the select gate line SGD. The interconnect layer 24 includes, for example, tungsten.

The interconnect layer 25 is stacked above the insulating layer 44. The interconnect layer 25 is formed in, for example, a line shape extending along the Y direction. The interconnect layer 25 is used as the bit line BL. In a region (not illustrated), the interconnect layers 25 are arranged along the X direction. The interconnect layer 25 includes, for example, copper.

The insulating layer 45 is stacked above the interconnect layer 25. The insulating layer 45 includes, for example, a plurality of interconnects (not illustrated) for connecting to the row decoder module 16, the sense amplifier module 17, and the like in which the memory cell array 10 is further provided above.

Each of the memory pillars MP is provided to extend along the Z direction. Each of the memory pillars MP penetrates the wiring layers 22 to 24 and the insulating layers 41 to 43.

Each of the memory pillars MP includes, for example, a core film 30, a semiconductor film 31, and a stacked film 32. The core film 30 is provided to extend along the Z direction. For example, the upper end of the core film 30 is located in the insulating layer 44, and the lower end of the core film is located in the interconnect layer 21. The core film 30 includes, for example, an insulator such as silicon oxide (SiO). The semiconductor film 31 covers the periphery of the core film 30, for example. At the lower end of the memory pillar MP, a part of the semiconductor film 31 is in contact with the interconnect layer 21. The semiconductor film 31 includes, for example, silicon. The stacked film 32 covers the side surface of the semiconductor film 31 except for a portion where the semiconductor film 31 and the interconnect layer 21 are in contact with each other.

In the structure of the memory pillar MP illustrated in FIG. 5, a portion where the memory pillar MP and the interconnect layer 22 intersect with each other functions as the select transistor ST2. Portions where the memory pillars MP intersect with the respective interconnect layers 23 function as memory cell transistors MT0 to MT7, respectively. A portion where the memory pillar MP and the interconnect layer 24 intersect each other functions as the select transistor ST1.

A columnar contact CCV is provided on the upper surface of the semiconductor film 31 in the memory pillar MP. In the region illustrated in FIG. 5, two contacts CCV corresponding to the two memory pillars MP among the six memory pillars MP are illustrated. Another contact CCV is connected in a region (not illustrated) to the memory pillar MP that does not overlap the member SHE in the region and is not connected to the contact CCV.

One interconnect layer 25, that is, one bit line BL is in contact with the upper surface of each contact CCV. One contact CCV is connected to one interconnect layer 25 in each of the spaces divided by the members SLT and SHE. That is, for example, one memory pillar MP in each region between the adjacent members SLT and SHE and one memory pillar MP in each region between the two adjacent members SHE are electrically connected to each of the interconnect layers 25.

The member SLT is formed to extend along the XZ plane, for example. Each of the members SLT divides the interconnect layers 22 to 24 and the insulating layers 41 to 43 in the Y direction.

In the member SLT, the contact LI is provided so as to extend along the XZ plane, and the spacer SP is provided between the contact LI and the interconnect layers 22 to 24 and the insulating layers 41 to 44. The upper end of the contact LI is located, for example, in the insulating layer 44. The lower end of the contact LI is located, for example, in the interconnect layer 21. Note that the contact LI may be omitted according to the structure of the memory cell array 10.

The member SHE is formed in, for example, a plate shape extending along the XZ plane and divides the interconnect layer 24. The upper end of the member SHE is located in the insulating layer 44. The lower end of the member SHE is located, for example, in the uppermost insulating layer 43. The member SHE includes, for example, an insulator such as silicon oxide. Note that the upper end of the member SHE and the upper end of the member SLT may be aligned or may not be aligned. In addition, the upper end of the member SHE and the upper end of the memory pillar MP may be aligned or may not be aligned.

### 1.1.4.4 Cross-Sectional Structure of Memory Pillar

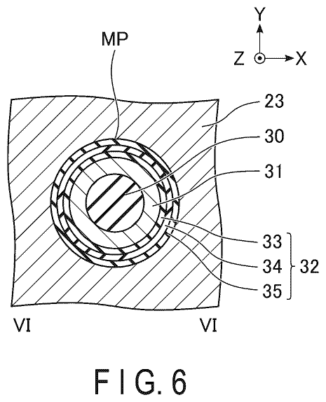

FIG. 6 is a cross-sectional view taken along the line VI-VI of FIG. 5, illustrating an example of a cross-sectional structure of the memory pillar MP. More specifically, FIG. 6 illustrates a cross-sectional structure of the memory pillar MP in the XY plane including the interconnect layer 23. As illustrated in FIG. 6, the stacked film 32 includes, for example, a tunnel insulating film 33, a charge storage film 34, and a block insulating film 35.

In the cross section including the interconnect layer 23, the core film 30 is provided, for example, at the central portion of the memory pillar MP. The semiconductor film 31 surrounds the side surface of the core film 30. The tunnel insulating film 33 surrounds the side surface of the semiconductor film 31. The charge storage film 34 surrounds the side surface of the tunnel insulating film 33. The block insulating film 35 surrounds the side surface of the charge storage film 34. The interconnect layer 23 surrounds the side surface of the block insulating film 35.

The semiconductor film 31 is used as a channel (current path) of each of the memory cell transistors MT0 to MT7 and the select transistors ST1 and ST2. The tunnel insulating film 33 is used as a potential barrier between the semiconductor film 31 and the charge storage film 34, and includes, for example, silicon oxide. The charge storage film 34 has a function of accumulating charges, and includes, for example, silicon nitride (SiN). The block insulating film 35 suppresses back tunneling of charges from the interconnect layer 23 to the memory pillar MP, and includes, for example, silicon oxide. With this configuration, each memory pillar MP can function as the NAND string NS.

### 1.1.5 Circuit Configuration of Row Decoder Module

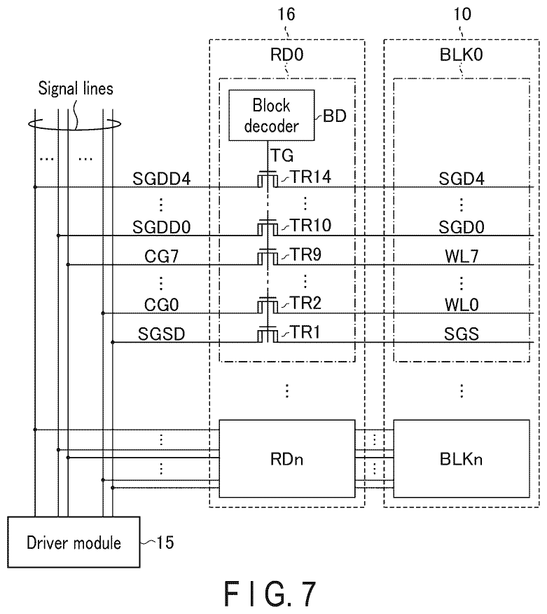

A circuit configuration of the row decoder module 16 will be described with reference to FIG. 7. FIG. 7 is a circuit diagram illustrating an example of the circuit configuration of the row decoder module 16. As illustrated in FIG. 7, the row decoder module 16 includes, for example, row decoders RD0 to RDn. Hereinafter, in a case where the row decoders RD0 to RDn are not distinguished, they are simply referred to as row decoders RD.

The row decoder RD is used to select the block BLK. The row decoders RD0 to RDn are associated with the blocks BLK0 to BLKn, respectively.

Hereinafter, a detailed circuit configuration of the row decoder RD will be described focusing on the row decoder RD0 corresponding to the block BLK0. The row decoders RD1 to RDn also have the same configuration as the row decoder RD0.

The row decoder RD includes, for example, a block decoder BD and transistors TR1 to TR14.

The block decoder BD decodes the block address BA. The block decoder BD applies a predetermined voltage to the transfer gate line TG based on the decoding result. The transfer gate line TG is commonly connected to the gates of the transistors TR1 to TR14.

The transistors TR1 to TR14 include, for example, high-voltage N-channel metal oxide semiconductor field effect transistors (MOSFET) having durability against a voltage VPGM to be described later. The transistors TR1 to TR14 are connected between various signal lines wired from the driver module 15 and various interconnects of the associated block BLK. In the following description, in a case where the source and the drain of the transistor are not limited, one of the source and the drain of the transistor is referred to as “first end of the transistor”, and the other of the source and the drain of the transistor is referred to as “second end of the transistor”. A state in which the first end and the second end of the transistor are electrically connected via the transistor is referred to as an “ON state”, and a state in which the first end and the second end are electrically insulated via the transistor is referred to as an “OFF state”.

Specifically, to the driver module 15, the signal lines SGDD0 to SGDD4, the signal lines CG0 to CG7, and the signal line SGSD are connected. The signal lines SGDD0 to SGDD4 correspond to the select gate lines SGD0 to SGD4, respectively. The signal lines CG0 to CG7 correspond to the word lines WL0 to WL7, respectively. The signal line SGSD corresponds to the select gate line SGS.

A first end of the transistor TR1 is connected to the signal line SGSD. A second end of the transistor TR1 is connected to the select gate line SGS. First ends of the transistors TR2 to TR9 are connected to the signal lines CG0 to CG7, respectively. Second ends of the transistors TR2 to TR9 are connected to the word lines WL0 to WL7, respectively. First ends of the transistors TR10 to TR14 are connected to the signal lines SGDD0 to SGDD4, respectively. Second ends of the transistors TR10 to TR14 are connected to the select gate lines SGD0 to SGD4, respectively.

With the above configuration, the row decoder module 16 can select the block BLK that executes various operations.

Specifically, during various operations, the block decoder BD corresponding to the selected block BLK applies a voltage at an “H” level to the transfer gate line TG, and the block decoder BD corresponding to the non-selected block BLK applies a voltage at an “L” level to the transfer gate line. For example, in a case where the block BLK0 is selected, the transistors TR1 to TR14 included in the row decoder RD0 are turned on, and the transistors TR1 to TR14 included in the row decoders RD1 to RDn are turned off. In this case, current paths between the various interconnects provided in the block BLK0 and the corresponding signal lines are formed, and current paths between the various interconnects provided in the blocks BLK1 to BLKn and the corresponding signal lines are blocked. As a result, the voltage applied to each signal line by the driver module 15 is applied, via the row decoder RD0, to various interconnects provided in the selected block BLK0. The row decoder module 16 can operate in a similar manner even in a case where a different block BLK is selected.

### 1.1.6 Circuit Configuration of Driver Module

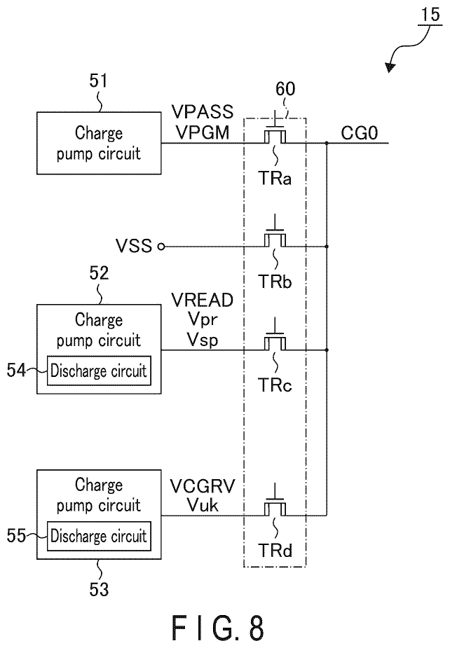

A circuit configuration of the driver module 15 will be described with reference to FIG. 8. FIG. 8 is a circuit diagram illustrating an example of the circuit configuration of the driver module 15. FIG. 8 illustrates a configuration in which a voltage is applied to the signal line CG0 in the driver module 15. The configuration for applying a voltage to the other signal lines CG is also similar to that in FIG. 8. As illustrated in FIG. 8, the driver module 15 includes charge pump circuits 51, 52, and 53, and a CG select driver 60.

Each of the charge pump circuits 51, 52, and 53 is a circuit that boosts an input voltage, adjusts the voltage to a predetermined voltage value, and output the voltage. The charge pump circuit 51 outputs voltages VPASS and VPGM to be described later. The charge pump circuit 52 outputs voltages VREAD, Vpr, and Vsp to be described later. The voltages Vpr and Vsp are variable. The charge pump circuit 53 outputs voltages VCGRV and Vuk to be described later. The voltages VCGRV and Vuk are variable.

The charge pump circuit 52 includes a discharge circuit 54. The discharge circuit 54 is a discharge circuit with a level control function. The discharge circuit 54 discharges the voltage of the word line WL according to a state of a threshold voltage distribution formed by the memory cell transistor MT to be described later, for example.

The charge pump circuit 53 includes a discharge circuit 55. The discharge circuit 55 is a discharge circuit with a level control function. The discharge circuit 55 discharges the voltage of the word line WL according to the state of the threshold voltage distribution formed by the memory cell transistor MT, for example.

The CG select driver 60 includes transistors TRa to TRd. Each of the transistors TRa to TRd includes, for example, a high-voltage N-channel MOSFET. A first end of the transistor TRa is connected to the signal line CG0. A second end of the transistor TRa is connected to the charge pump circuit 51. A first end of the transistor TRb is connected to the signal line CG0. To a second end of the transistor TRb, a voltage VSS is applied. The voltage VSS is, for example, a ground voltage. A first end of the transistor TRc is connected to the signal line CG0. A second end of the transistor TRc is connected to the charge pump circuit 52. A first end of the transistor TRd is connected to the signal line CG0. A second end of the transistor TRd is connected to the charge pump circuit 53. The CG select driver 60 transfers the voltage to the signal line CG0 or discharges the voltage of the word line WL via the signal line CG0 by selecting one of the transistors TRa to TRd and turning on the selected transistor under the control of the sequencer 14. Note that the number of transistors TR included in the CG select driver 60 may be any number.

### 1.2 Data Storage Method

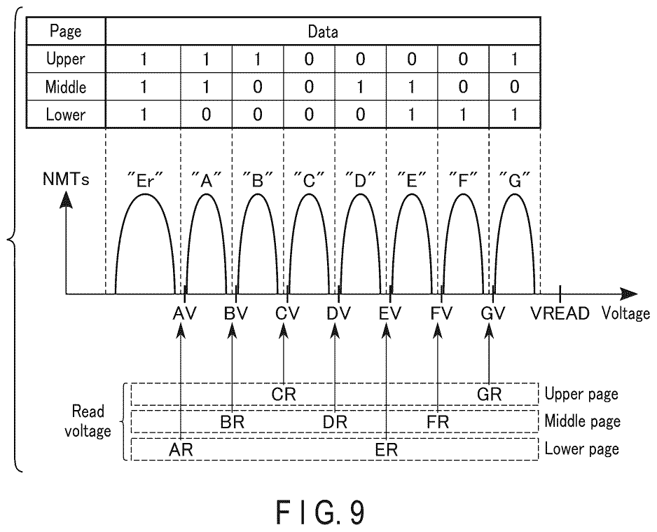

A data storage method will be described with reference to FIG. 9. FIG. 9 is a conceptual diagram illustrating an example of the data storage method. FIG. 9 illustrates an example of a threshold voltage distribution of the memory cell transistor MT, data allocation, the voltage used for a data read operation, and a voltage used for the verify operation. In the threshold voltage distribution diagram illustrated in FIG. 9, the vertical axis represents the number (NMTs) of the memory cell transistors MT, and the horizontal axis represents the voltage applied to the gates of the memory cell transistors MT.

As illustrated in FIG. 9, in a case where one memory cell transistor MT is a TLC that stores 3-bit data, there may be eight types of states in the threshold voltage distribution formed by the memory cell transistors MT included in the cell unit CU. Hereinafter, the eight types of states will be referred to as “Er” state, “A” state, “B” state, “C” state, “D” state, “E” state, “F” state, and “G” state, respectively, in order from a lower threshold voltage.

In a case where the memory cell transistor MT is in the erase state, the threshold voltage of the memory cell transistor MT is included in “Er” state. In a case where data is written in the memory cell transistor MT, the threshold voltage of the memory cell transistor MT is included in any of “Er” to “G” states. Different pieces of 3-bit data are allocated to “Er” to “G” states, respectively. The data allocation in each of two adjacent states is preferably set such that only 1-bit data is different. Hereinafter, an example of data allocation to the eight types of states will be listed.
“Er” state: “111 (upper bit/middle bit/lower bit)” data
“A” state: “110” data
“B” state: “100” data
“C” state: “000” data
“D” state: “010” data
“E” state: “011” data
“F” state: “001” data
“G” state: “101” data

A verify voltage used to confirm a data write operation and a read voltage used for a data read operation are set between the adjacent states. Specifically, the verify voltage AV and the read voltage AR are set between the “Er” and “A” states. Between the “A” and “B” states, the verify voltage BV and the read voltage BR are set. Between the “B” and “C” states, the verify voltage CV and the read voltage CR are set. Between the “C” and “D” states, the verify voltage DV and the read voltage DR are set. Between the “D” and “E” states, the verify voltage EV and the read voltage ER are set. Between the “E” and “F” states, the verify voltage FV and the read voltage FR are set. Between the “F” and “G” states, the verify voltage GV and the read voltage GR are set. The verify voltages AV to GV are preferably set to be higher than the read voltages AR to GR, respectively.

The verify voltages AV to GV are associated with “A” to “G” states, respectively.

The read voltage AR is used to distinguish between the “Er” state and the “A” state or above. The read voltage BR is used to distinguish between the “A” state or below and the “B” state or above. The read voltage CR is used to distinguish between the “B” state or below and the “C” state or above. The read voltage DR is used to distinguish between the “C” state or below and the “D” state or above. The read voltage ER is used to distinguish between the “D” state or below and the “E” state or above. The read voltage FR is used to distinguish between the “E” state or below and the “F” state or above. The read voltage GR is used to distinguish between the “F” state or below and the “G” state or above. In addition, a read path voltage VREAD is set to a voltage higher than that in the highest state. The memory cell transistor MT having the gate to which the read path voltage VREAD is applied is turned on regardless of the stored data.

In the read operation, the semiconductor memory device 3 uses at least one read voltage to determine in which state the memory cell transistor MT is distributed. For example, lower page data that is a set of pieces of lower bit data is determined by a read operation using each of the read voltages AR and ER. Middle page data that is a set of pieces of middle bit data is determined by a read operation using each of the read voltages BR, DR, and FR. Upper page data that is a set of pieces of upper bit data, is determined by a read operation using each of the read voltages CR and GR. In a page read operation using a plurality of read voltages, arithmetic processing is appropriately executed.

In a case where the memory cell transistor MT is the TLC (hereinafter, referred to as a “TLC method”), the semiconductor memory device 3 may use other data allocations. Furthermore, the semiconductor memory device 3 may use a storage method other than the TLC method, and any data allocation can be used. For example, one memory cell transistor MT may store 2-bit data, 4-bit data, or larger bit data. The operations described in the specification can be executed regardless of the data storage method or the type of data allocation.

### 1.3 Write Operation

The write operation will be described. In the following description, a signal line CG that is selected is referred to as a “selected signal line” in the write operation. A signal line CG that is not selected is referred to as a “non-selected signal line”. The selected word line WL is referred to as a “word line WLsel”. The non-selected word line WL is referred to as a “word line WLusel”. The memory cell transistor MT connected to the word line WLsel is referred to as a “memory cell transistor MTsel”. The memory cell transistor MT connected to the word line WLusel is referred to as a “memory cell transistor MTusel”.

### 1.3.1 Overview of Write Operation

The write operation includes a program operation and a verify operation. In the write operation, a plurality of program loops each including a program operation and a verify operation are sequentially executed, so that the threshold voltage of the memory cell transistor MT is increased to a target level.

The program operation is an operation of increasing the threshold voltage by injecting electrons into the charge storage film (or maintaining the threshold voltage by prohibiting injection). In the program operation, the plurality of memory cell transistors MTsel connected to the word line WLsel are set to be programmed or prohibited from being programmed based on write data. Specifically, the memory cell transistor MTsel that has not reached the threshold voltage of the write target state (hereinafter, referred to as a “write state”) is set as a program target. On the other hand, the memory cell transistor MTsel that has reached the threshold voltage of the write state is set to program prohibition.

In the program operation, the voltage VPASS is applied to the word line WLusel, and the program voltage VPGM is applied to the word line WLsel. The voltage VPASS is a voltage that turns on the memory cell transistor MT regardless of the threshold voltage of the memory cell transistor MT. The voltage VPGM is a high voltage capable of increasing the threshold voltage of the memory cell transistor MT. The voltage VPGM is stepped up, for example, according to the repetition of the program loops. That is, the voltage VPGM may be high according to the number of program loops executed. The step-up width DVPGM of the voltage VPGM can be set to an arbitrary value. As well as the voltage VPGM, the voltage VPASS is stepped up with an arbitrary step-up width DVPASS according to repetition of the program loops. In a case where the voltage VPGM is applied to the word line WLsel, the threshold voltage of the memory cell transistor MTsel connected to the word line WLsel and connected to the bit line BL to be programmed increases. On the other hand, an increase in the threshold voltage of the memory cell transistor MTsel connected to the word line WLsel and connected to the bit line BL in which programming is prohibited is suppressed by a self-boost technology or the like. Upon completion of the program operation, the sequencer 14 executes the verify operation.

The verify operation is a read operation to confirm whether or not the threshold voltage of the memory cell transistor MTsel has reached the threshold voltage of the write state. In the same program loop, the verify operation is executed on the memory cell transistor MTsel that is set as a program target and coincides with the write state to be verified.

In the verify operation, the voltage VREAD is applied to the word line WLusel, and the verify voltage VCGRV is applied to the word line WLsel. In a case where the voltage is applied to the bit line BL, the sense amplifier unit SAU determines whether the threshold voltage of the memory cell transistor MTsel exceeds the verify voltage applied to the word line WLsel based on the voltage of the bit line BL. Each sense amplifier unit SAU determines, as “Verify passed”, a memory cell transistor MTsel that can be considered to have the threshold voltage exceeding the verify voltage, that is, having reached the threshold voltage of the write state. On the other hand, each sense amplifier unit SAU determines, as “Verify failed”, the memory cell transistor MTsel that can be considered to have the threshold voltage equal to or lower than the verify voltage, that is, having not reached the threshold voltage of the write state. Each sense amplifier unit SAU stores the verify result of the write state described above in any internal latch circuit. In a case where the verify operation ends, the sequencer 14 sets each memory cell transistor MTsel to be programmed or prohibited from being programmed based on the verify result in the current program loop, and starts a process of the next program loop.

Note that the semiconductor memory device 3 can appropriately execute a detection operation after each program loop. In the detection operation, the number of memory cell transistors MTsel that have passed the verify operation is counted for each write state. Then, the sequencer 14 determines whether or not writing of the write state has been completed based on the count value for each write state. For example, in the repetition of the program loops, in a case where it is detected that the number of the memory cell transistors MTsel that have not passed the verify operation of “A” to “G” states is less than a predetermined number, the sequencer 14 ends the write operation.

### 1.3.2 Specific Example of Program Loops

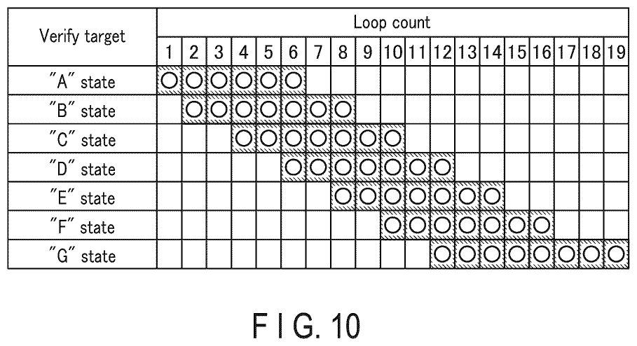

A specific example of the program loops will be described with reference to FIG. 10. FIG. 10 is a table illustrating an example of settings of the program loops in the write operation. The table illustrated in FIG. 10 indicates the relationship between the loop count and the write states to be verified that are allocated to the loops, and white circles are drawn in portions where the verify operation is set.

As illustrated in FIG. 10, the type and number of write states to be verified can be changed according to the progress of the program loops. In this example, the sequencer 14 executes the program loop up to 19 times. Then, the sequencer 14 executes a verify operation for at least one type of state in each of the 19 program loops.

Specifically, “A” state is set as a verify target in the first to sixth program loops. “B” state is set as a verify target in the second to eighth program loops. “C” state is set as a verify target in the fourth to tenth program loops. “D” state is set as a verify target in the sixth to 12th program loops. “E” state is set as a verify target in the eighth to 14th program loops. “F” state is set as a verify target in the 10th to 16th program loops. “G” state is set as a verify target in the 12th to 19th program loops.

The number of program loops that can be executed by the semiconductor memory device 3 in one write operation may be another number of times. Even in a case where writing is not completed in all the write states, the sequencer 14 can end the write operation in response to execution of a predetermined number of program loops. The write state to be verified associated with the loop count may be another setting. The sequencer 14 may omit the program operation and the verify operation of the write state in the subsequent program loop based on the result of the detection operation.

### 1.3.3 Details of Write Operation

Details of the write operation will be described. In the following description, the voltage applied to the word line WLsel in a case where the voltage VREAD is applied to the word line WLusel is referred to as a “voltage Vwl”.

According to the present embodiment, the sequencer 14 applies the voltage Vwl to the word line WLsel in a case of applying the voltage VREAD to the word line WLusel in the verify operation on the memory cell transistor MTsel, and then applies the verify voltage VCGRV according to the write state to the word line WLsel. In addition, the sequencer 14 changes the voltage level of the voltage Vwl according to the progress of the program loops.

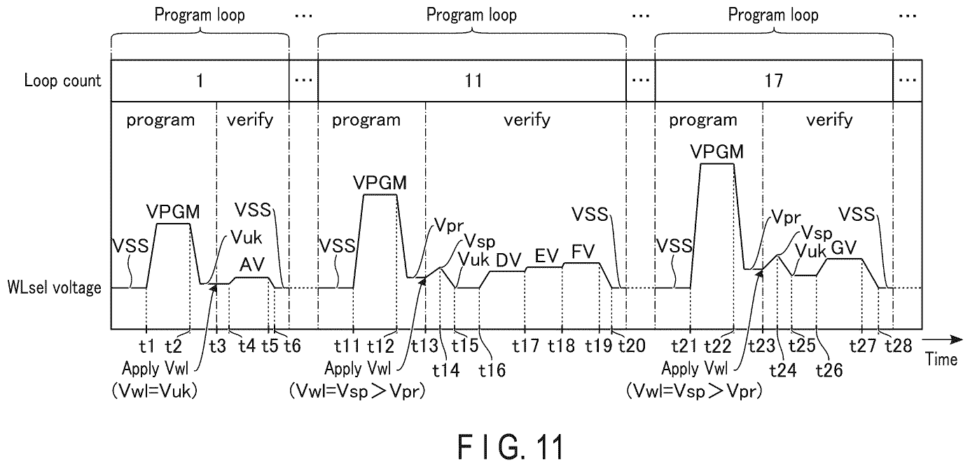

The voltage of the word line WLsel in the write operation will be described with reference to FIG. 11. FIG. 11 is a timing chart illustrating an example of the voltage of the word line WLsel in the write operation of the semiconductor memory device 3 according to the first embodiment. FIG. 11 illustrates the first program loop, the 11th program loop, and the 17th program loop of the first to 19th program loops illustrated in FIG. 10 as representative examples. FIG. 11 illustrates the voltage at the near end (Near) for the voltage of the word line WLsel.

### (First Program Loop)

As illustrated in FIG. 11, at the start of the first program loop, the voltage of the word line WLsel is, for example, the voltage VSS.

In a case where the first program loop starts, the sequencer 14 executes the program operation in the period from time t1 to time t2 and executes a program recovery operation in the period from time t2 to time t3, for example. The program recovery operation is an operation of adjusting a voltage level for executing the verify operation. In addition, the sequencer 14 executes the verify operation in a period from time t3 to time t5, and executes a verify recovery operation in a period from time t5 to time t6, for example. The verify recovery operation is an operation of adjusting a voltage level for executing the next program loop. In the period from time t4 to time t5, determination of Verify passed or a Verify failed using the verify voltage AV (hereinafter, referred to as “verify determination”) is performed.

At time t1, the program operation starts. More specifically, the voltage VPGM is supplied from the charge pump circuit 51, whereby the voltage VPGM is applied to the selected signal line CG. For example, the voltage at the near end (Near) of the word line WLsel gradually rises to reach the voltage VPGM. The voltage at the far end (Far) of the word line WLsel increases with a delay from that at the near end (Near).

In the period from the time t1 to the time t2, in a case where the voltage of the word line WLsel reaches the voltage VPGM, the potential difference (VPGM-VSS) between the word line WLsel and the channel (For example, the voltage VSS is applied via the corresponding bit line BL.) increases in the memory cell transistor MTsel to be programmed. As a result, electrons are trapped in the charge storage film, and the threshold voltage of the memory cell transistor MTsel is increased. On the other hand, in the memory cell transistor MTsel prohibited from being programmed, the potential difference between the word line WLsel and the channel (For example, a voltage of a predetermined magnitude is applied via the corresponding bit line BL.) is smaller than that of the memory cell transistor MTsel to be programmed. As a result, electrons are not trapped in the charge storage film due to the self-boost effect, and the threshold voltage of the memory cell transistor MTsel is maintained.

Next, at time t2, the program operation ends and the program recovery operation starts. More specifically, the voltage of the word line WLsel is discharged by the discharge circuit 55 of the charge pump circuit 53. At this time, an underkick voltage Vuk is supplied from the charge pump circuit 53, whereby the voltage Vuk is applied to the selected signal line CG. The voltage Vuk is, for example, a voltage lower than the verify voltage VCGRV applied in the same program loop. Since the load applied to the word line WLsel is large, the discharge takes time. By applying the voltage Vuk, for example, the voltage at the near end (Near) of the word line WLsel can be rapidly lowered, and the voltage at the far end (Far) of the word line WLsel can be lowered relatively quickly. In the period from time t2 to time t3, the voltage of the word line WLsel reaches the voltage Vuk. A period from time t2 to time t3 corresponds to a time required for discharge of the voltage of the word line WLsel by the discharge circuit 55 of the charge pump circuit 53. Hereinafter, a period from time t2 to time t3, that is, a time period during which the voltage of the word line WLsel is discharged from the voltage VPGM is defined as a “program recovery time period Tpr”. For example, the program recovery time period Tpr is the same in all the loops.

Next, at time t3, the program recovery operation ends and the verify operation starts. More specifically, the voltage VREAD is supplied from the charge pump circuit 52, whereby the voltage VREAD is applied to the non-selected signal line CG. At this time, the voltage Vuk remains applied to the selected signal line CG. That is, at time t3, in a case where the voltage VREAD is applied to the word line WLusel, a voltage equal to the voltage Vuk is applied to the word line WLsel as the voltage Vwl.

As described above, in the first program loop, after the program operation, the operation (hereinafter, referred to as a “first control operation”) of applying the voltage Vuk that is a voltage after discharging the voltage of the word line WLsel as the voltage Vwl to the word line WLsel in a case where the voltage VREAD is applied to the word line WLusel is executed. That is, after the program operation, the voltage Vwl is set to the voltage Vuk that is a voltage after discharging the voltage of the word line WLsel.

Next, at time t4, the voltage AV is supplied as the voltage VCGRV from the charge pump circuit 53, whereby the verify voltage AV is applied to the selected signal line CG. By increasing the voltage of the word line WLsel, the residual electrons in the channel in the memory cell transistor MTsel are removed, and the verify determination is appropriately performed. Hereinafter, the period from time t3 to time t4, that is, the period from the start of the verify operation (the end of the program recovery operation) to the application of the verify voltage AV to the word line WLsel is defined as “verify initial time period Td”.

Thereafter, at time t5, the verify operation ends, and the verify recovery operation starts. More specifically, the voltage VSS is applied to the selected signal line CG by connecting the selected signal line CG to the voltage VSS of the driver module 15. At time t6, in a case where the voltage of the word line WLsel reaches the voltage VSS, the verify recovery operation ends. As a result, the first program loop ends.

### (11th Program Loop)

As illustrated in FIG. 11, at the start of the 11th program loop, the voltage of the word line WLsel is, for example, the voltage VSS.

In a case where the 11th program loop starts, the sequencer 14 executes the program operation in the period from time t11 to time t12 and executes the program recovery operation in the period from time t12 to time t13, for example. In addition, the sequencer 14 executes the verify operation in the period from time t13 to time t19, and executes the verify recovery operation in the period from time t19 to time t20. In the period from time t16 to time t19, a verify determination using the verify voltage DV, a verify determination using the verify voltage EV, and a verify determination using the verify voltage FV are performed.

At time t11, the program operation starts. More specifically, the voltage VPGM is supplied from the charge pump circuit 51, whereby the voltage VPGM is applied to the selected signal line CG. The voltage VPGM is higher than the voltage VPGM in the 10th program loop. For example, the voltage at the near end (Near) of the word line WLsel gradually rises to reach the voltage VPGM. The voltage at the far end (Far) of the word line WLsel increases with a delay from that at the near end (Near).

In a case where the voltage of the word line WLsel reaches the voltage VPGM in the period from time t1l to time t12, the threshold voltage of the memory cell transistor MTsel to be programmed is increased, and the threshold voltage of the memory cell transistor MTsel prohibited from being programmed is maintained.

Next, at time t12, the program operation ends and the program recovery operation starts. More specifically, the voltage of the word line WLsel is discharged by the discharge circuit 54 of the charge pump circuit 52. At this time, the recovery voltage Vpr is supplied from the charge pump circuit 52, whereby the voltage Vpr is applied to the selected signal line CG. The voltage Vpr is, for example, a voltage higher than the voltage Vuk applied in the same program loop. By applying the voltage Vpr, for example, the voltage at the near end (Near) of the word line WLsel can be rapidly lowered, and the voltage at the far end (Far) of the word line WLsel can be lowered relatively quickly. In addition, by applying the voltage Vpr, power consumption can be reduced, and program disturb or read disturb can be suppressed. In the period from time t12 to time t13, the voltage of the word line WLsel reaches the voltage Vpr. The period from time t12 to time t13 corresponds to a time required for discharging the voltage of the word line WLsel by the discharge circuit 54 of the charge pump circuit 52. The period from time t12 to time t13 is the program recovery time period Tpr.

Next, at time t13, the program recovery operation ends and the verify operation starts. More specifically, the voltage VREAD is supplied from the charge pump circuit 52, whereby the voltage VREAD is applied to the non-selected signal line CG. At this time, the voltage Vsp is supplied from the charge pump circuit 52, whereby the voltage Vsp is applied to the selected signal line CG. That is, at time t13, in a case where the voltage VREAD is applied to the word line WLusel, the voltage Vsp higher than the voltage Vpr is applied to the word line WLsel as the voltage Vwl. The voltage Vwl (Vsp) is higher than that of the program loop preceding the 11th program loop and lower than that of the program loop following the 11th program loop. In the period from time t13 to time t14, the voltage of the word line WLsel reaches the voltage Vsp.

As described above, in the 11th program loop, after the program operation, the operation (hereinafter, referred to as a “second control operation”) of discharging the voltage of the word line WLsel to the voltage Vpr and then applying the voltage Vsp increased from the voltage Vpr to the word line WLsel as the voltage Vwl in a case where the voltage VREAD is applied to the word line WLusel is executed. That is, after the program operation, the voltage Vwl is set to the voltage Vsp obtained by discharging the voltage of the word line WLsel to the voltage Vpr and then increasing the voltage Vpr.

Next, at time t14, the voltage of the word line WLsel is discharged by the discharge circuit 55 of the charge pump circuit 53. At this time, an underkick voltage Vuk is supplied from the charge pump circuit 53, whereby the voltage Vuk is applied to the selected signal line CG. That is, at time t14, the voltage Vuk lower than the voltage Vsp is applied to the word line WLsel. The voltage Vuk is, for example, a voltage lower than the verify voltage VCGRV applied in the same program loop. By applying the voltage Vuk, for example, the voltage at the near end (Near) of the word line WLsel can be rapidly lowered, and the voltage at the far end (Far) of the word line WLsel can be lowered relatively quickly. In the period from time t14 to time t15, the voltage of the word line WLsel reaches the voltage Vuk.

Next, at time t16, the voltage DV is supplied as the voltage VCGRV from the charge pump circuit 53, so that the verify voltage DV is applied to the selected signal line CG, and the verify determination is performed. The period from time t13 to time t16, that is, the period from the start of the verify operation (the end of the program recovery operation) to the application of the verify voltage DV to the word line WLsel is the verify initial time period Td. In other words, in the 11th program loop, the verify initial time period Td is the total period of time for charging the voltage of the word line WLsel to the voltage Vsp and the time for discharging the voltage of the word line WLsel from the voltage Vsp to the voltage Vuk. At time t17, the voltage EV is supplied as the voltage VCGRV from the charge pump circuit 53, whereby the verify voltage EV is applied to the selected signal line CG, and the verify determination is performed. At time t18, the voltage FV is supplied as the voltage VCGRV from the charge pump circuit 53, whereby the verify voltage FV is applied to the selected signal line CG, and the verify determination is performed.

Thereafter, at time t19, the verify operation ends, and the verify recovery operation starts. More specifically, the voltage VSS is applied to the selected signal line CG by connecting the selected signal line CG to the voltage VSS of the driver module 15. At time t20, in a case where the voltage of the word line WLsel reaches the voltage VSS, the verify recovery operation ends. As a result, the 11th program loop ends.

### (17th Program Loop)

As illustrated in FIG. 11, at the start of the 17th program loop, the voltage of the word line WLsel is, for example, the voltage VSS.

In a case where the 17th program loop starts, the sequencer 14 executes the program operation in the period from time t21 to time t22 and executes the program recovery operation in the period from time t22 to time t23, for example. In addition, the sequencer 14 executes the verify operation in the period from time t23 to time t27, and executes the verify recovery operation in the period from time t27 to time t28. In the period from time t26 to time t27, the verify determination using the verify voltage GV is performed.

At time t21, the program operation starts. More specifically, the voltage VPGM is supplied from the charge pump circuit 51, whereby the voltage VPGM is applied to the selected signal line CG. The voltage VPGM is higher than the voltage VPGM in the 16th program loop. For example, the voltage at the near end (Near) of the word line WLsel gradually rises to reach the voltage VPGM. The voltage at the far end (Far) of the word line WLsel increases with a delay from that at the near end (Near).

In the period from time t21 to time t22, in a case where the voltage of the word line WLsel reaches the voltage VPGM, the threshold voltage of the memory cell transistor MTsel to be programmed is increased, and the threshold voltage of the memory cell transistor MTsel prohibited from being programmed is maintained.

Next, at time t22, the program operation ends and the program recovery operation starts. More specifically, the voltage of the word line WLsel is discharged by the discharge circuit 54 of the charge pump circuit 52. At this time, the recovery voltage Vpr is supplied from the charge pump circuit 52, whereby the voltage Vpr is applied to the selected signal line CG. The voltage Vpr is, for example, a voltage higher than the voltage Vuk applied in the same program loop. By applying the voltage Vpr, for example, the voltage at the near end (Near) of the word line WLsel can be rapidly lowered, and the voltage at the far end (Far) of the word line WLsel can be lowered relatively quickly. In the period from time t22 to time t23, the voltage of the word line WLsel reaches the voltage Vpr. The period from time t22 to time t23 corresponds to a time required for discharging the voltage of the word line WLsel by the discharge circuit 54 of the charge pump circuit 52. The period from time t22 to time t23 is the program recovery time period Tpr.

Next, at time t23, the program recovery operation ends and the verify operation starts. More specifically, the voltage VREAD is supplied from the charge pump circuit 52, whereby the voltage VREAD is applied to the non-selected signal line CG. At this time, the voltage Vsp is supplied from the charge pump circuit 52, whereby the voltage Vsp is applied to the selected signal line CG. That is, at time t23, in a case where the voltage VREAD is applied to the word line WLusel, the voltage Vsp higher than the voltage Vpr is applied to the word line WLsel as the voltage Vwl. The voltage Vsp is, for example, a voltage VREAD. The voltage Vwl (Vsp) is higher than that of the program loop preceding the 17th program loop and lower than that of the program loop following the 17th program loop. In the period from time t23 to time t24, the voltage of the word line WLsel reaches the voltage Vsp.

As described above, in the 17th program loop, after the program operation, the second control operation of discharging the voltage of the word line WLsel to the voltage Vpr and then applying the voltage Vsp obtained by increasing the voltage Vpr as the voltage Vwl to the word line WLsel in a case where the voltage VREAD is applied to the word line WLusel is executed. That is, after the program operation, the voltage Vwl is set to the voltage Vsp obtained by discharging the voltage of the word line WLsel to the voltage Vpr and then increasing the voltage Vpr.

Next, at time t24, the voltage of the word line WLsel is discharged by the discharge circuit 55 of the charge pump circuit 53. At this time, an underkick voltage Vuk is supplied from the charge pump circuit 53, whereby the voltage Vuk is applied to the selected signal line CG. That is, at time t24, the voltage Vuk lower than the voltage Vsp is applied to the word line WLsel. The voltage Vuk is, for example, a voltage lower than the verify voltage VCGRV applied in the same program loop. By applying the voltage Vuk, for example, the voltage at the near end (Near) of the word line WLsel can be rapidly lowered, and the voltage at the far end (Far) of the word line WLsel can be lowered relatively quickly. In the period from time t24 to time t25, the voltage of the word line WLsel reaches the voltage Vuk.

Next, at time t26, the voltage GV is supplied as the voltage VCGRV from the charge pump circuit 53, whereby the verify voltage GV is applied to the selected signal line CG, and the verify determination is performed. The period from time t23 to time t26 is the verify initial time period Td. In other words, in the 17th program loop, the verify initial time period Td is the total period of time for charging the voltage of the word line WLsel to the voltage Vsp and the time for discharging the voltage of the word line WLsel from the voltage Vsp to the voltage Vuk.

Thereafter, at time t27, the verify operation ends, and the verify recovery operation starts. More specifically, the voltage VSS is applied to the selected signal line CG by connecting the selected signal line CG to the voltage VSS of the driver module 15. At time t28, in a case where the voltage of the word line WLsel reaches the voltage VSS, the verify recovery operation ends. As a result, the 17th program loop ends.

### (Details of Voltage of Word Line WL)

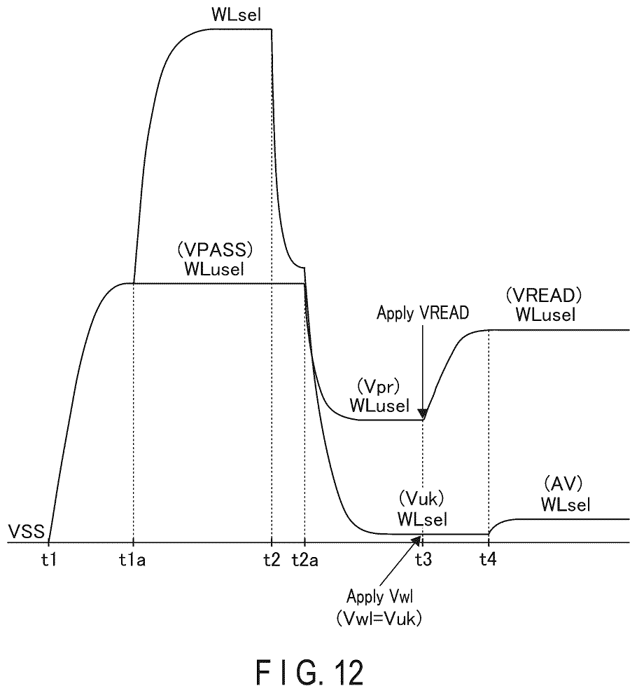

FIG. 12 is a timing chart illustrating, in more detail, an example of the voltage of the word line WLsel in the write operation of the semiconductor memory device 3 according to the first embodiment. FIG. 12 also illustrates the voltage of the word line WLusel. FIG. 12 corresponds to, for example, the first program loop illustrated in FIG. 11.

As illustrated in FIG. 12, at time t1, the program operation starts, and the voltage VPASS is applied to each of the non-selected signal line CG and the selected signal line CG. At time t1a, the voltage VPGM is applied to the selected signal line CG. In the period from time t1 to time t2, the voltage of the word line WLusel reaches the voltage VPASS, and the voltage of the word line WLsel reaches the voltage VPGM.

Next, at time t2, the program operation ends, the program recovery operation starts, and the voltage VPASS is applied to the selected signal line CG. At time t2a, the recovery voltage Vpr is applied to the non-selected signal line CG, and the underkick voltage Vuk is applied to the selected signal line CG. In the period from time t2 to time t3, the voltage of the word line WLusel reaches the voltage Vpr, and the voltage of the word line WLsel reaches the voltage Vuk.

Next, at time t3, the program recovery operation ends, the verify operation starts, and the voltage VREAD is applied to the non-selected signal line CG. At this time, the voltage of the selected signal line CG is maintained at the voltage Vuk. In other words, the voltage Vuk is applied as the voltage Vwl to the selected signal line CG. In the period from time t3 to time t4, the voltage of the word line WLusel reaches the voltage VREAD, and the voltage of the word line WLsel is maintained at the voltage Vuk.

Next, at time t4, the verify voltage AV is applied to the selected signal line CG, and a verify determination is performed.

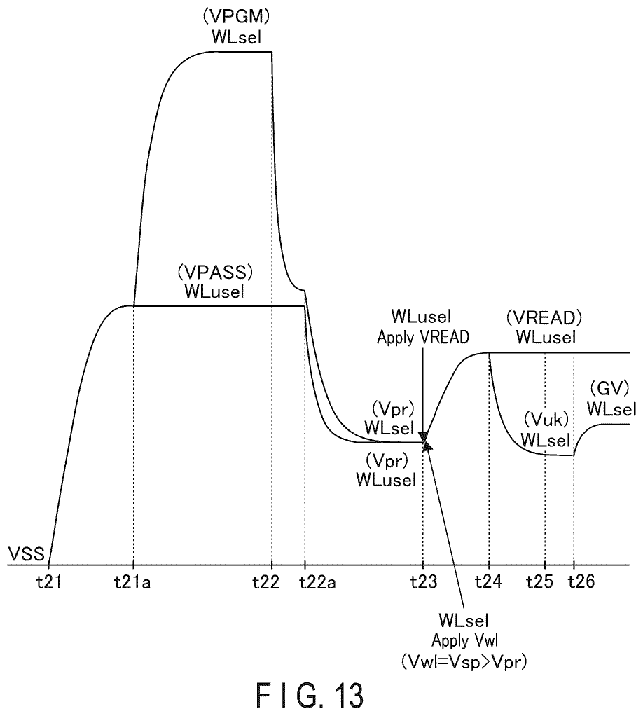

FIG. 13 is a timing chart illustrating, in more detail, an example of the voltage of the word line WLsel in the write operation of the semiconductor memory device 3 according to the first embodiment. FIG. 13 also illustrates the voltage of the word line WLusel. FIG. 13 corresponds to, for example, the 17th program loop illustrated in FIG. 11.

As illustrated in FIG. 13, at time t21, the program operation starts, and the voltage VPASS is applied to each of the non-selected signal line CG and the selected signal line CG. At time t21a, the voltage VPGM is applied to the selected signal line CG. In the period from time t21 to time t22, the voltage of the word line WLusel reaches the voltage VPASS, and the voltage of the word line WLsel reaches the voltage VPGM.

Next, at time t22, the program operation ends, the program recovery operation starts, and the voltage VPASS is applied to the selected signal line CG. At time t22a, the recovery voltage Vpr is applied to each of the non-selected signal line CG and the selected signal line CG. In the period from time t22 to time t23, the voltage of each of the word lines WLusel and WLsel reaches the voltage Vpr.

Next, at time t23, the program recovery operation ends, the verify operation starts, the voltage VREAD is applied to the non-selected signal line CG, and the voltage Vsp is applied as the voltage Vwl to the selected signal line CG. The voltage Vsp is higher than the voltage Vpr. In the period from time t23 to time t24, the voltage of the word line WLusel reaches the voltage VREAD, and the voltage of the word line WLsel reaches the voltage Vsp.

Next, at time t24, the underkick voltage Vuk is applied to the selected signal line CG. The voltage Vuk is lower than the voltage Vsp. In the period from time t24 to time t25, the voltage of the word line WLsel reaches the voltage Vuk.

Next, at time t26, the verify voltage GV is applied to the selected signal line CG, and a verify determination is performed.

The timing chart illustrating, in more detail, an example of the voltage of the word line WLsel in the 11th program loop illustrated in FIG. 11 is also similar to FIG. 13.

### (Method of Controlling Voltage Vwl)

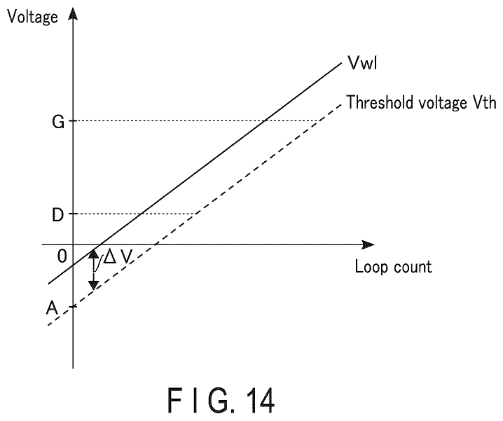

A method of controlling the voltage Vwl will be described with reference to FIG. 14. FIG. 14 is a diagram illustrating an example of a method of controlling the voltage Vwl applied to the word line WLsel in the write operation of the semiconductor memory device 3 according to the first embodiment. In FIG. 14, the vertical axis represents the voltage, and the horizontal axis represents the loop count of the program loops. The voltage Vwl is indicated by the solid line, and the threshold voltage Vth of the write target memory cell transistor MTsel is indicated by the broken line.

As illustrated in FIG. 14, in the write operation, the threshold voltage Vth of the write target memory cell transistor MTsel increases at a constant rate as the program loop progresses, for example. In the example of FIG. 14, the threshold voltage Vth of the memory cell transistor MTsel in “A” state is, for example, a negative value. The threshold voltage Vth of the memory cell transistor MTsel in “D” state and the threshold voltage Vth of the memory cell transistor MTsel in “G” state are, for example, positive values. The threshold voltage Vth of the memory cell transistor MTsel in “G” state is higher than the threshold voltage Vth of the memory cell transistor MTsel in “D” state.

As illustrated in FIG. 14, according to the present embodiment, the voltage Vwl is set to a voltage higher than the threshold voltage Vth by the voltage difference ΔV according to the loop count. That is, the voltage level of the voltage Vwl is increased as the program loop proceeds.

For example, among the write states except for “Er” state, before the program loop in which the verify operation for the middle state starts, the first control operation is executed to set the voltage level of the voltage Vwl to a voltage higher than the threshold voltage Vth by the voltage difference ΔV. After the program loop in which the verify operation for the middle state starts, the second control operation is executed to set the voltage level of the voltage Vwl to a voltage higher than the threshold voltage Vth by the voltage difference ΔV. In a case where there are seven write states of “A” state to “G” state except for “Er” state, the middle state is, for example, “D” state, but may not be “D” state, and may be “C” state or “E” state that are relatively close to “D” state.

The verify initial time period Td in the program loop in which the first control operation is executed is set shorter than the verify initial time period Td in the program loop in which the second control operation is executed.

By being controlled as described above, in the plurality of program loops including the first loop, the second loop after the first loop, and the third loop after the second loop, the voltage Vwl (hereinafter, referred to as a “voltage Vwl2”) in the second loop is higher than the voltage Vwl (hereinafter, referred to as a “voltage Vwl1”) in the first loop. The voltage Vwl (hereinafter, referred to as a “voltage Vwl3”) in the third loop is higher than the voltage Vwl2 in the second loop. In the first loop, the voltage Vwl1 is lower than the verify voltage. In the second loop, the voltage Vwl2 is higher than the verify voltage. In the third loop, the voltage Vwl3 is higher than the verify voltage.

### 1.4 Effects According to Present Embodiment

In the verify operation, in a case where the voltage VREAD is not applied to the word line WLsel when the voltage VREAD is applied to the word line WLusel, there is a possibility that the memory cell transistor MTusel is turned on but the memory cell transistor MTsel is not turned on in the NAND string NS. In a case where the memory cell transistor MTsel is not turned on, the channel of the memory cell transistor MTusel is boosted, and the channel may be disconnected in a region corresponding to the memory cell transistor MTsel. In this case, gate induced drain leakage (GIDL) may occur. In a case where GIDL occurs, hot carrier injection (HCI) occurs in the charge storage film due to a high field effect, which may lead to rewriting of data stored in the memory cell transistor MT and deterioration of circuit characteristics of the memory cell transistor MT. That is, the occurrence of GIDL leads to a decrease in the reliability of the memory cell.

As a method of suppressing the occurrence of GIDL, there is a method of applying the voltage VREAD to the word line WLsel in a case of applying the voltage VREAD to the word line WLusel in the verify operation. However, in this method, since the verify voltage is applied to the word line WLsel after raising and lowering the voltage of the word line WLsel to the voltage VREAD, the time required for the write operation becomes relatively long.

According to the present embodiment, the voltage level of the voltage Vwl applied to the word line WLsel in a case of applying the voltage VREAD to the word line WLusel is changed according to the progress of the program loop.

Here, a case will be considered in which a verify initial time period Td in a case where the first control operation is executed is set in the program loop in which the verify operation for a relatively low state is performed, and the first control operation is executed at the verify initial time period Td in the program loop in which the verify operation for the middle state and a relatively high state is performed. In this case, in the program loop in which the verify operation for the relatively high state is performed, since the threshold voltage Vth is relatively high, there is a possibility that the voltage of the word line WLsel becomes lower than the threshold voltage Vth due to the application of the voltage Vuk. In addition, in the program loop in which the verify operation for the middle state is performed, the threshold voltage Vth is relatively low, but there is a possibility that the voltage of the word line WLsel becomes lower than the threshold voltage Vth due to the application of the voltage Vuk. In a case where there are seven write states of “A” state to “G” state except for “Er” state, the relatively low state is, for example, “A” state, but may not be “A” state, and may be “B” state that is relatively close to “A” state. The relatively high state is, for example, “G” state, but may not be “G” state, and may be “F” state that is relatively close to “G” state.

Therefore, according to the present embodiment, before the program loop in which the verify operation for the middle state starts, the first control operation is executed to set the voltage level of the voltage Vwl to a voltage higher than the threshold voltage Vth by the voltage difference ΔV. After the program loop in which the verify operation for the middle state starts, the second control operation is executed to set the voltage level of the voltage Vwl to a voltage higher than the threshold voltage Vth by the voltage difference ΔV.

As a result, during the write operation, in the verify operation of all the program loops, the voltage level of the voltage Vwl applied to the word line WLsel in a case of applying the voltage VREAD to the word line WLusel becomes higher than the threshold voltage Vth. Therefore, it is possible to suppress disconnection of the channel in the region corresponding to the memory cell transistor MTsel. That is, the occurrence of GIDL can be suppressed. Therefore, since the occurrence of HCI can be suppressed, deterioration of the reliability of the memory cell can be suppressed.

In addition, in the write operation, the first control operation is executed before the program loop in which the verify operation for the middle state starts. Therefore, the time required for the write operation can be shortened as compared with the case where the second control operation is executed in the verify operation of all the program loops.

### 2. Second Embodiment

A semiconductor memory device 3 according to a second embodiment will be described. In the semiconductor memory device 3 according to the second embodiment, the write operation is different from that of the first embodiment. Hereinafter, differences from the first embodiment will be described.

### 2.1 Details of Write Operation

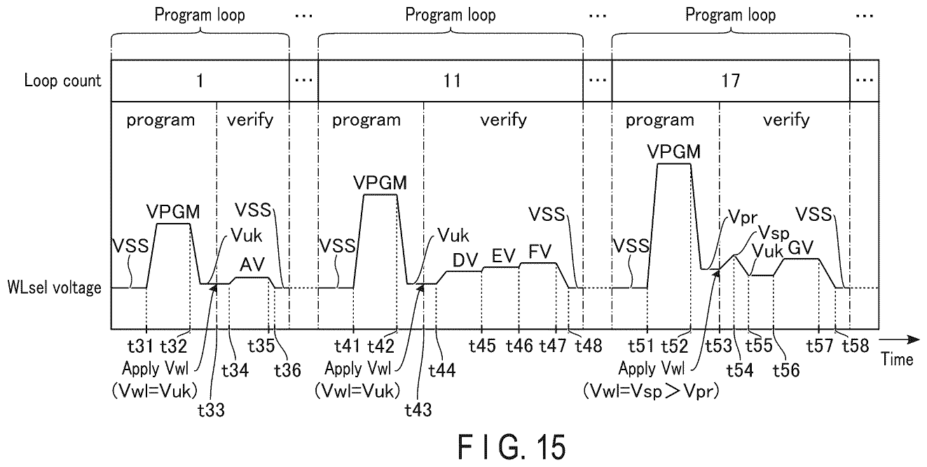

The voltage of the word line WLsel in the write operation will be described with reference to FIG. 15. FIG. 15 is a timing chart illustrating an example of the voltage of the word line WLsel in the write operation of the semiconductor memory device 3 according to the second embodiment. FIG. 15 illustrates the first program loop, the 11th program loop, and the 17th program loop, as representative examples, among the first to 19th program loops illustrated in FIG. 10. FIG. 15 illustrates the voltage at the near end (Near) regarding the voltage of the word line WLsel.

### (First Program Loop)

As illustrated in FIG. 15, the waveform of the voltage of the word line WLsel in the period from time t31 to time t36 is similar to the waveform of the voltage of the word line WLsel in the period from time t1 to time t6 in FIG. 11 illustrated in the first embodiment.

### (11th Program Loop)

As illustrated in FIG. 15, at the start of the 11th program loop, the voltage of the word line WLsel is, for example, the voltage VSS.

In a case where the 11th program loop starts, the sequencer 14 executes the program operation in the period from time t41 to time t42 and executes the program recovery operation in the period from time t42 to time t43, for example. In addition, the sequencer 14 executes the verify operation in the period from time t43 to time t47, and executes the verify recovery operation in the period from time t47 to time t48. In the period from time t44 to time t47, the verify determination using the verify voltage DV, the verify determination using the verify voltage EV, and the verify determination using the verify voltage FV are performed.

At time t41, the program operation starts, and the voltage VPGM is applied to the selected signal line CG. The voltage VPGM is higher than the voltage VPGM in the 10th program loop.

In the period from time t41 to time t42, in a case where the voltage of the word line WLsel reaches the voltage VPGM, the threshold voltage of the memory cell transistor MTsel to be programmed is increased, and the threshold voltage of the memory cell transistor MTsel prohibited from being programmed is maintained.

Next, at time t42, the program operation ends, the program recovery operation starts, and the underkick voltage Vuk is applied to the selected signal line CG. The voltage Vuk is, for example, a voltage higher than the verify voltage VCGRV applied in the same program loop. In the period from time t42 to time t43, the voltage of the word line WLsel reaches the voltage Vuk. The period from time t42 to time t43 corresponds to a time required for discharging the voltage of the word line WLsel by the discharge circuit 55 of the charge pump circuit 53. The period from time t42 to time t43 is the program recovery time period Tpr.

Next, at time t43, the program recovery operation ends, the verify operation starts, and the voltage VREAD is applied to the non-selected signal line CG. At this time, the voltage Vuk remains applied to the selected signal line CG. That is, at time t43, a voltage Vwl equal to the voltage Vuk is applied to the word line WLsel. In other words, at time t43, in a case where the voltage VREAD is applied to the word line WLusel, the voltage equal to the voltage Vuk is applied to the word line WLsel as the voltage Vwl.

As described above, in the 11th program loop, after the program operation, the first control operation of applying the voltage Vuk that is a voltage after discharging the voltage of the word line WLsel as the voltage Vwl to the word line WLsel in a case where the voltage VREAD is applied to the word line WLusel is executed. That is, after the program operation, the voltage Vwl is set to the voltage Vuk that is a voltage after discharging the voltage of the word line WLsel.

Next, at time t44, the verify voltage DV is applied to the selected signal line CG, and the verify determination is performed. The period from time t43 to time t44 is the verify initial time period Td. At time t45, the verify voltage EV is applied to the selected signal line CG, and the verify determination is performed. At time t46, the verify voltage FV is applied to the selected signal line CG, and the verify determination is performed.

Thereafter, at time t47, the verify operation ends, the verify recovery operation starts, and the voltage VSS is applied to the selected signal line CG. At time t48, in a case where the voltage of the word line WLsel reaches the voltage VSS, the verify recovery operation ends. As a result, the 11th program loop ends.

### (17th Program Loop)

As illustrated in FIG. 15, the waveform of the voltage of the word line WLsel in the period from time t51 to time t58 is similar to the waveform of the voltage of the word line WLsel in the period from the time t21 to the time t28 in FIG. 11 illustrated in the first embodiment.

### (Method of Controlling Voltage Vwl)

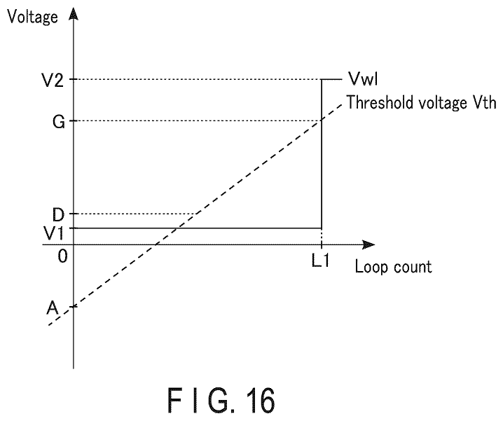

A method of controlling the voltage Vwl will be described with reference to FIG. 16. FIG. 16 is a diagram illustrating an example of the method of controlling the voltage Vwl applied to the word line WLsel in the write operation of the semiconductor memory device 3 according to the second embodiment. In FIG. 16, the vertical axis represents the voltage, and the horizontal axis represents the loop count of the program loop. The voltage Vwl is indicated by the solid line, and the threshold voltage Vth of the write target memory cell transistor MTsel is indicated by the broken line.

As illustrated in FIG. 16, according to the present embodiment, the voltage Vwl is set to a first value V1 before the loop count reaches a first loop count L1 that is relatively large. In a case where the loop count reaches the first loop count L1, the voltage Vwl is set to a second value V2 higher than the first value V1. That is, the voltage level of the voltage Vwl is set relatively low before reaching the end of the program loop, and set relatively high when reaching the end of the program loop.

For example, the first control operation is executed to set (fix) the voltage level of the voltage Vwl to the first value V1 before the program loop (first loop count L1) in which the verify operation for a relatively high state starts among the write states except for “Er” state. After the first loop count L1, the second control operation is executed to set (fix) the voltage level of the voltage Vwl to the second value V2. In a case where there are seven write states of “A” state to “G” state except for “Er” state, the relatively high state is, for example, “G” state, but is not limited thereto. The first value V1 is, for example, a value equal to or higher than the threshold voltage Vth of the memory cell transistor MTsel in “C” state and lower than the threshold voltage Vth of the memory cell transistor MTsel in “D” state, but is not limited thereto. The second value V2 is, for example, a value higher than the threshold voltage Vth of the memory cell transistor MTsel in “G” state, but is not limited thereto.

The verify initial time period Td in the program loop in which the first control operation is executed is set shorter than the verify initial time period Td in the program loop in which the second control operation is executed.

By being controlled as described above, in the program loops including the first loop, the second loop after the first loop, and the third loop after the second loop, the voltage Vwl3 in the third loop is higher than the voltage Vwl1 in the first loop and the voltage Vwl2 in the second loop. The voltage Vwl2 in the second loop is the same as the voltage Vwl1 in the first loop. Further, in the first loop, the voltage Vwl1 is lower than the verify voltage. In the second loop, the voltage Vwl2 is lower than the verify voltage. In the third loop, the voltage Vwl3 is higher than the verify voltage.

### 2.2 Effects According to Present Embodiment

GIDL may be generated in a case where a voltage Vdg (GIDL potential) between a drain and a gate of the memory cell transistor MTsel is relatively high. In addition, the voltage Vdg is affected by the voltage VPASS and the threshold voltage Vth of the memory cell transistor MTsel. In the program loop in which the verify operation for the middle state is performed, the voltage VPASS applied to the word line WLusel is lower and the threshold voltage Vth is also lower than those in the program loop in which the verify operation for a relatively high state is performed. Therefore, in the program loop in which the verify operation for the middle state is performed, the voltage Vdg is relatively likely to not reach the voltage at which GIDL can occur.

Therefore, according to the present embodiment, before the program loop in which the verify operation for a relatively high state starts, the first control operation is executed to set the voltage Vwl to the first value V1. After the program loop in which the verify operation for the relatively high state starts, the second control operation is executed to set the voltage Vwl to the second value V2 higher than the first value V1.

As a result, during the write operation, in the verify operation of all the program loops, even in a case where the voltage level of the voltage Vwl applied to the word line WLsel when applying the voltage VREAD to the word line WLusel is lower than the threshold voltage Vth, the occurrence of GIDL can be suppressed. Therefore, since the occurrence of HCI can be suppressed, deterioration of the reliability of the memory cell can be suppressed.

In addition, in the write operation, the first control operation is executed before the program loop in which the verify operation for a relatively high state starts. Therefore, the time required for the write operation can be shortened as compared with the case where the second control operation is executed in the verify operation of all the program loops.

Furthermore, in each of the program loop in which the verify operation for a relatively low state is performed and the program loop in which the verify operation for the relatively high state is performed, the period from when the voltage Vwl is applied until the voltage of the word line WLsel converges to the verify voltage can be shortened.

### 3. Third Embodiment

A semiconductor memory device 3 according to a third embodiment will be described. In the semiconductor memory device 3 according to the third embodiment, the write operation is different from that of the first embodiment. Hereinafter, differences from the first embodiment will be described.

### 3.1 Details of Write Operation

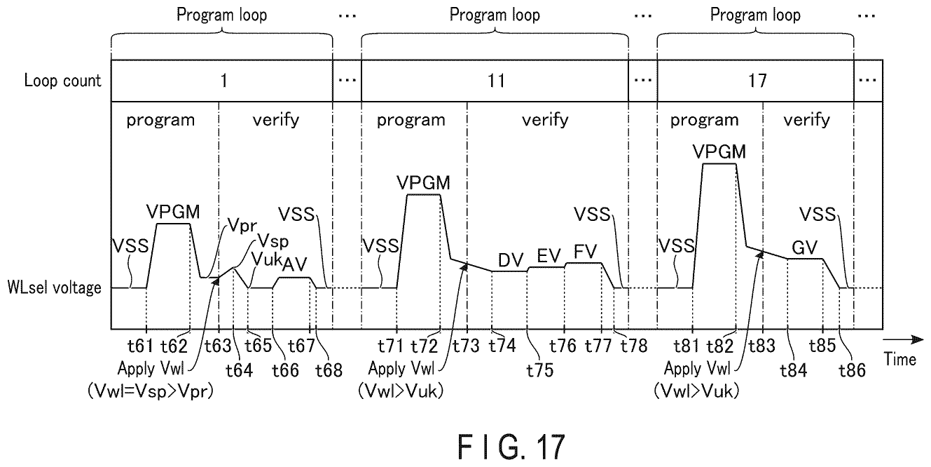

The voltage of the word line WLsel in the write operation will be described with reference to FIG. 17. FIG. 17 is a timing chart illustrating an example of the voltage of the word line WLsel in the write operation of the semiconductor memory device 3 according to the third embodiment. FIG. 17 illustrates the first program loop, the 11th program loop, and the 17th program loop among the first to 19th program loops illustrated in FIG. 10 as representative examples. FIG. 17 illustrates voltage at the near end (Near) for the voltage of the word line WLsel.

### (First Program Loop)

As illustrated in FIG. 17, at the start of the first program loop, the voltage of the word line WLsel is, for example, the voltage VSS.

In a case where the first program loop starts, the sequencer 14 executes the program operation in the period from time t61 to time t62 and executes the program recovery operation in the period from time t62 to time t63, for example. In addition, the sequencer 14 executes the verify operation in the period from time t63 to time t67, and executes the verify recovery operation in the period from time t67 to time t68. During the period from time t66 to time t67, the verify determination using the verify voltage AV is performed.

At time t61, the program operation starts, and the voltage VPGM is applied to the selected signal line CG.

In a case where the voltage of the word line WLsel reaches the voltage VPGM in the period from time t61 to time t62, the threshold voltage of the memory cell transistor MTsel to be programmed is increased, and the threshold voltage of the memory cell transistor MTsel prohibited from being programmed is maintained.

Next, at time t62, the program operation ends, a program recovery operation starts, and a recovery voltage Vpr is applied to the selected signal line CG. In the period from time t62 to time t63, the voltage of the word line WLsel reaches the voltage Vpr. The period from time t62 to time t63 is the program recovery time period Tpr.

Next, at time t63, the program recovery operation ends, the verify operation starts, and the voltage VREAD is applied to the non-selected signal line CG. At this time, a voltage Vsp is applied to the selected signal line CG. That is, at time t63, in a case where the voltage VREAD is applied to the word line WLusel, the voltage Vsp higher than the voltage Vpr is applied to the word line WLsel as the voltage Vwl. The voltage Vsp is, for example, the voltage VREAD. In the period from time t63 to time t64, the voltage of the word line WLsel reaches the voltage Vsp.

As described above, in the first program loop, after the program operation, the second control operation of discharging the voltage of the word line WLsel to the voltage Vpr and then applying the voltage Vsp obtained by increasing the voltage Vpr as the voltage Vwl to the word line WLsel in a case where the voltage VREAD is applied to the word line WLusel is executed. That is, after the program operation, the voltage Vwl is set to the voltage Vsp obtained by discharging the voltage of the word line WLsel to the voltage Vpr and then increasing the voltage Vpr.

Next, at time t64, the underkick voltage Vuk is applied to the selected signal line CG. That is, at time t64, the voltage Vuk lower than the voltage Vsp is applied to the word line WLsel. The voltage Vuk is, for example, a voltage lower than the verify voltage applied in the same program loop. In the period from time t64 to time t65, the voltage of the word line WLsel reaches the voltage Vuk.

Next, at time t66, the verify voltage ΔV is applied to the selected signal line CG, and the verify determination is performed. The period from time t63 to time t66 is the verify initial time period Td.

Thereafter, at time t67, the verify operation ends, the verify recovery operation starts, and the voltage VSS is applied to the selected signal line CG. At time t68, in a case where the voltage of the word line WLsel reaches the voltage VSS, the verify recovery operation ends. As a result, the first program loop ends.

### (11th Program Loop)

As illustrated in FIG. 17, at the start of the 11th program loop, the voltage of the word line WLsel is, for example, the voltage VSS.

In a case where the 11th program loop starts, the sequencer 14 executes the program operation in the period from time t71 to time t72 and executes the program recovery operation in the period from time t72 to time t73, for example. In addition, the sequencer 14 executes the verify operation in the period from time t73 to time t77, and executes the verify recovery operation in the period from time t77 to time t78, for example. In the period from time t74 to time t77, the verify determination using the verify voltage DV, the verify determination using the verify voltage EV, and the verify determination using the verify voltage FV are performed.

At time t71, the program operation starts, and the voltage VPGM is applied to the selected signal line CG.

In a case where the voltage of the word line WLsel reaches the voltage VPGM in the period from time t71 to time t72, the threshold voltage of the memory cell transistor MTsel to be programmed is increased, and the threshold voltage of the memory cell transistor MTsel prohibited from being programmed is maintained.

Next, at time t72, the program operation ends and the program recovery operation starts. More specifically, the voltage of the word line WLsel is discharged by the discharge circuit 55 of the charge pump circuit 53. At this time, the underkick voltage Vuk is supplied from the charge pump circuit 53, whereby the voltage Vuk is applied to the selected signal line CG. The voltage Vuk is, for example, a voltage lower than the verify voltage VCGRV applied in the same program loop. In the period from time t72 to time t73, the voltage of the word line WLsel drops to a voltage higher than the voltage Vuk. The period from time t72 to time t73 is the program recovery time period Tpr.

Next, at time t73, the program recovery operation ends and the verify operation starts. More specifically, the voltage VREAD is supplied from the charge pump circuit 52, whereby the voltage VREAD is applied to the non-selected signal line CG. At this time, the voltage Vuk remains applied to the selected signal line CG, but at time t73, the voltage of the word line WLsel is discharged only to a voltage lower than the voltage VPGM and higher than the verify voltage DV. That is, at time t73, in a case where the voltage VREAD is applied to the word line WLusel, a voltage lower than the voltage VPGM and higher than the verify voltage DV is applied as the voltage Vwl to the word line WLsel.

As described above, in the 11th program loop, after the program operation, the first control operation is executed to apply the voltage (a voltage during discharging to the voltage Vuk) after discharging the voltage of the word line WLsel as the voltage Vwl to the word line WLsel in a case where the voltage VREAD is applied to the word line WLusel. That is, after the program operation, the voltage Vwl is set to the voltage after discharging the voltage of the word line WLsel (a voltage during discharging to the voltage Vuk).

Next, at time t74, the verify voltage DV is applied to the selected signal line CG, and the verify determination is performed. The period from time t73 to time t74 is the verify initial time period Td. At time t75, the verify voltage EV is applied to the selected signal line CG, and the verify determination is performed. At time t76, the verify voltage FV is applied to the selected signal line CG, and the verify determination is performed.

Thereafter, at time t77, the verify operation ends, the verify recovery operation starts, and the voltage VSS is applied to the selected signal line CG. At time t78, in a case where the voltage of the word line WLsel reaches the voltage VSS, the verify recovery operation ends. As a result, the 11th program loop ends.

### (17th Program Loop)

As illustrated in FIG. 17, at the start of the 17th program loop, the voltage of the word line WLsel is, for example, the voltage VSS.

In a case where the 17th program loop starts, the sequencer 14 executes the program operation in the period from time t81 to time t82 and executes the program recovery operation in the period from time t82 to time t83, for example. In addition, the sequencer 14 executes the verify operation in the period from time t83 to time t85, and executes the verify recovery operation in the period from time t85 to time t86, for example. In the period from time t84 to time t85, the verify determination using the verify voltage GV is performed.

At time t81, the program operation starts, and the voltage VPGM is applied to the selected signal line CG.

In a case where the voltage of the word line WLsel reaches the voltage VPGM in the period from time t81 to time t82, the threshold voltage of the memory cell transistor MTsel to be programmed is increased, and the threshold voltage of the memory cell transistor MTsel prohibited from being programmed is maintained.

Next, at time t82, the program operation ends and the program recovery operation starts. More specifically, the voltage of the word line WLsel is discharged by the discharge circuit 55 of the charge pump circuit 53. At this time, the underkick voltage Vuk is supplied from the charge pump circuit 53, whereby the voltage Vuk is applied to the selected signal line CG. The voltage Vuk is, for example, a voltage lower than the verify voltage VCGRV applied in the same program loop. In the period from time t82 to time t83, the voltage of the word line WLsel drops to a voltage higher than the voltage Vuk. The period from time t82 to time t83 is the program recovery time period Tpr.

Next, at time t83, the program recovery operation ends and the verify operation starts. More specifically, the voltage VREAD is supplied from the charge pump circuit 52, whereby the voltage VREAD is applied to the non-selected signal line CG. At this time, the voltage Vuk remains applied to the selected signal line CG, but at time t83, the voltage of the word line WLsel is discharged only to a voltage lower than the voltage VPGM and higher than the verify voltage GV. That is, at time t83, in a case where the voltage VREAD is applied to the word line WLusel, a voltage lower than the voltage VPGM and higher than the verify voltage GV is applied to the word line WLsel as the voltage Vwl.

As described above, in the 17th program loop, after the program operation, the first control operation is executed to apply the voltage (a voltage during discharging to the voltage Vuk) after discharging the voltage of the word line WLsel as the voltage Vwl to the word line WLsel in a case where the voltage VREAD is applied to the word line WLusel. That is, after the program operation, the voltage Vwl is set to a voltage after discharging the voltage of the word line WLsel (a voltage during discharging to the voltage Vuk).

Next, at time t84, the verify voltage GV is applied to the selected signal line CG, and the verify determination is performed. The period from time t83 to time t84 is the verify initial time period Td.

Thereafter, at time t85, the verify operation ends, the verify recovery operation starts, and the voltage VSS is applied to the selected signal line CG. At time t86, in a case where the voltage of the word line WLsel reaches the voltage VSS, the verify recovery operation ends. As a result, the 17th program loop ends.

### (Method of Controlling Voltage Vwl)

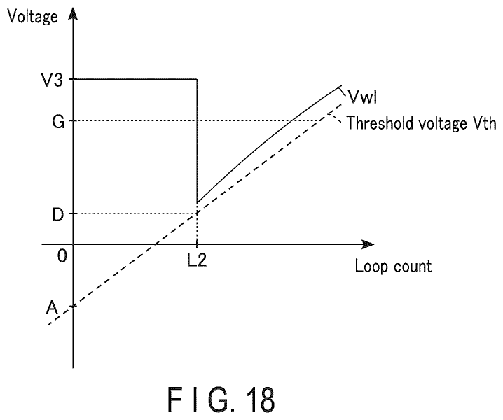

A method of controlling the voltage Vwl will be described with reference to FIG. 18. FIG. 18 is a diagram for describing an example of a method of controlling the voltage Vwl applied to the word line WLsel in the write operation of the semiconductor memory device 3 according to the third embodiment. In FIG. 18, the vertical axis represents the voltage, and the horizontal axis represents the loop count of the program loops. The voltage Vwl is indicated by the solid line, and the threshold voltage Vth of the write target memory cell transistor MTsel is indicated by the broken line.

As illustrated in FIG. 18, according to the present embodiment, the voltage Vwl is set to the third value V3 before the loop count reaches the second loop count L2 around the median value. In a case where the loop count reaches the second loop count L2, the voltage Vwl is set to a voltage higher than the threshold voltage Vth and lower than the third value V3. That is, the voltage level of the voltage Vwl is set relatively high before reaching the middle of the program loop, and set relatively low in a case of reaching the middle of the program loop.

For example, among the write states except for “Er” state, before the program loop (the second loop count L2) in which the verify operation for the middle state starts, the second control operation is executed to set (fix) the voltage level of the voltage Vwl to the third value V3. After the second loop count L2, the first control operation is executed to set the voltage level of the voltage Vwl to a voltage higher than the threshold voltage Vth and lower than the third value V3 (a voltage during discharge to the voltage Vuk). In a case where there are seven write states of “A” state to “G” state except for “Er” state, the middle state is, for example, “D” state, but is not limited thereto. The third value V3 is, for example, a value higher than the threshold voltage Vth of the memory cell transistor MTsel in “G” state, but is not limited thereto.

The verify initial time period Td in the program loop in which the first control operation is executed is set shorter than the verify initial time period Td in the program loop in which the second control operation is executed.

By being controlled as described above, in the program loops including the first loop, the second loop after the first loop, and the third loop after the second loop, the voltage Vwl1 in the first loop is higher than the voltage Vwl2 in the second loop and the voltage Vwl3 in the third loop. In the first loop, the voltage Vwl1 is higher than the verify voltage. In the second loop, the voltage Vwl2 is higher than the verify voltage. In the third loop, the voltage Vwl3 is higher than the verify voltage.

### 3.2 Effects According to Present Embodiment

First, a case will be considered in which a verify initial time period Td in a case where the first control operation is executed is set in a program loop in which the verify operation is performed for a relatively high state, and the first control operation is executed at the verify initial time period Td in a program loop in which the verify operation is performed for a relatively low state and a middle state. In this case, in the program loop in which the verify operation for the relatively low state is performed, since the voltage VPGM is relatively low, there is a possibility that the voltage of the word line WLsel is excessively lowered by the application of the voltage Vuk and becomes lower than the threshold voltage Vth. In addition, in the program loop in which the verify operation for the middle state is performed, since the threshold voltage Vth is relatively low, there is a relatively low possibility that the voltage of the word line WLsel becomes lower than the threshold voltage Vth in the middle of discharging from the voltage VPGM to the voltage Vuk.

Therefore, according to the present embodiment, before the program loop in which the verify operation for the middle state starts, the second control operation is executed to set the voltage Vwl to the third value V3. After the program loop in which the verify operation for the middle state starts, the first control operation is executed to set the voltage Vwl to a voltage higher than the threshold voltage Vth and lower than the third value V3.

With this configuration, the occurrence of GIDL can be suppressed during the write operation as in the first embodiment. Therefore, since the occurrence of HCI can be suppressed, deterioration of the reliability of the memory cell can be suppressed.

In addition, in the write operation, the first control operation is executed after the program loop in which the verify operation for the middle state starts. Therefore, the time required for the write operation can be shortened as compared with the case where the second control operation is executed in the verify operation of all the program loops.

### 4. Fourth Embodiment

A semiconductor memory device 3 according to a fourth embodiment will be described. In the semiconductor memory device 3 according to the fourth embodiment, the write operation is different from that of the first embodiment. Hereinafter, differences from the first embodiment will be described.

### 4.1 Details of Write Operation

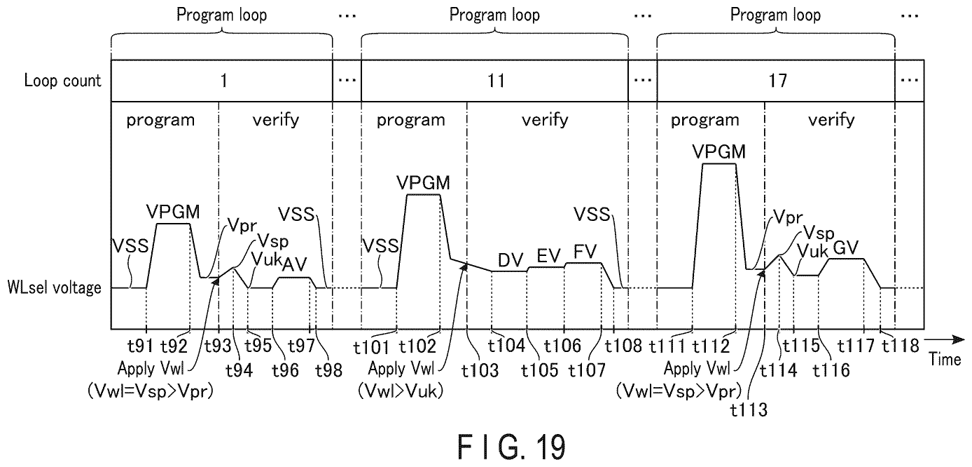

The voltage of the word line WLsel in the write operation will be described with reference to FIG. 19. FIG. 19 is a timing chart illustrating an example of the voltage Vwl of the word line WLsel in the write operation of the semiconductor memory device 3 according to the fourth embodiment. FIG. 19 illustrates the first program loop, the 11th program loop, and the 17th program loop among the first to 19th program loops illustrated in FIG. 10 as representative examples. FIG. 19 illustrates voltage at the near end (Near) regarding the voltage of the word line WLsel.

### (First Program Loop)

As illustrated in FIG. 19, the waveform of the voltage of the word line WLsel in the period from time t91 to time t98 is similar to the waveform of the voltage of the word line WLsel in the period from the time t61 to the time t68 in FIG. 17 illustrated in the third embodiment.

### (11th Program Loop)

As illustrated in FIG. 19, the waveform of the voltage of the word line WLsel in the period from time t101 to time t108 is similar to the waveform of the voltage of the word line WLsel in the period from the time t71 to the time t78 in FIG. 17 illustrated in the third embodiment.

### (17th Program Loop)

As illustrated in FIG. 19, the waveform of the voltage of the word line WLsel in the period from time till to time t118 is similar to the waveform of the voltage of the word line WLsel in the period from the time t21 to the time t28 in FIG. 11 illustrated in the first embodiment.

### (Method of Controlling Voltage Vwl)

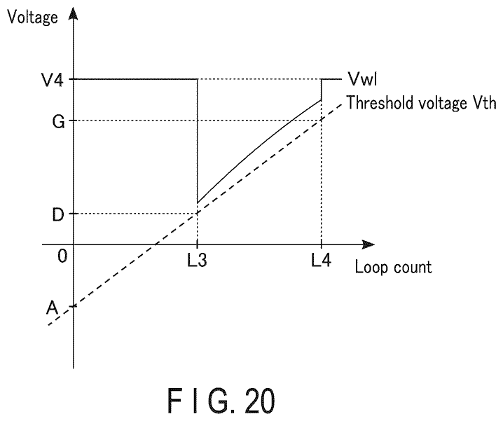

A method of controlling the voltage Vwl will be described with reference to FIG. 20. FIG. 20 is a diagram for describing an example of a method of controlling the voltage Vwl applied to the word line WLsel in the write operation of the semiconductor memory device 3 according to the fourth embodiment. In FIG. 20, the vertical axis represents the voltage, and the horizontal axis represents the loop count of the program loops. The voltage Vwl is indicated by the solid line, and the threshold voltage Vth of the write target memory cell transistor MTsel is indicated by the broken line.

As illustrated in FIG. 20, according to the present embodiment, the voltage Vwl is set to a fourth value V4 before the loop count reaches the third loop count L3 around the median value. Before the loop count reaches the third loop count L3 and reaches a relatively large fourth loop count L4, the voltage Vwl is set to a voltage higher than the threshold voltage Vth and lower than the fourth value V4. In a case where the loop count reaches the fourth loop count L4, the voltage Vwl is set to the fourth value V4. That is, the voltage level of the voltage Vwl is set to be relatively high before reaching the middle of the program loop, set to be relatively low before reaching the end from the middle of the program loop, and set to be relatively high when reaching the end of the program loop.

For example, the second control operation is executed to set (fix) the voltage level of the voltage Vwl to the fourth value V4 before the program loop (third loop count L3) in which the verify operation for the middle state starts among the write states except for “Er” state. After the third loop count L3 and before the program loop (fourth loop count L4) in which the verify operation for a relatively high state starts, the first control operation is executed to set the voltage level of the voltage Vwl to a voltage higher than the threshold voltage Vth and lower than the fourth value V4. After the fourth loop count L4, the second control operation is executed to set (fix) the voltage level of the voltage Vwl to the fourth value V4. In a case where there are seven write states of “A” state to “G” state except for “Er” state, the middle state is, for example, “D” state, but is not limited thereto. The relatively high state is, for example, “G” state, but is not limited thereto. The fourth value V4 is, for example, a value higher than the threshold voltage Vth of the memory cell transistor MTsel in “G” state, but is not limited thereto.

The verify initial time period Td in the program loop in which the first control operation is executed is set shorter than the verify initial time period Td in the program loop in which the second control operation is executed.

By being controlled as described above, in the program loops including the first loop, the second loop after the first loop, and the third loop after the second loop, the voltage Vwl1 in the first loop and the voltage Vwl3 in the third loop are higher than the voltage Vwl2 in the second loop. In the first loop, the voltage Vwl1 is higher than the verify voltage. In the second loop, the voltage Vwl2 is higher than the verify voltage. In the third loop, the voltage Vwl3 is higher than the verify voltage.

### 4.2 Effects According to Present Embodiment

First, a case will be considered in which a verify initial time period Td in a case where the first control operation is executed is set in the program loop in which the verify operation for the middle state is performed, and the first control operation is executed at the verify initial time period Td in the program loop in which each of the verify operations for a relatively low state and a relatively high state is performed. In this case, in the program loop in which the verify operation is performed for the relatively low state, since the voltage VPGM is relatively low, there is a possibility that the voltage of the word line WLsel is excessively lowered by the application of the voltage Vuk and becomes lower than the threshold voltage Vth. In addition, in the program loop in which the verify operation for the relatively high state is performed, since the threshold voltage Vth is relatively high, there is a possibility that the voltage of the word line WLsel becomes lower than the threshold voltage Vth in the middle of discharging from the voltage VPGM to the voltage Vuk.

Therefore, according to the present embodiment, before the program loop in which the verify operation for the middle state starts, the second control operation is executed to set the voltage Vwl to the fourth value V4. After the program loop in which the verify operation for the middle state starts and in the program loop in which the verify operation for a relatively high state starts, the first control operation is executed to set the voltage Vwl to a voltage higher than the threshold voltage Vth and lower than the fourth value V4. After the program loop in which the verify operation for the relatively high state starts, the second control operation is executed to set the voltage Vwl to the fourth value V4.

With this configuration, the occurrence of GIDL can be suppressed during the write operation as in the first embodiment. Therefore, since the occurrence of HCI can be suppressed, deterioration of the reliability of the memory cell can be suppressed.

In addition, in the write operation, the first control operation is executed after the program loop in which the verify operation for the middle state starts and before the program loop in which the verify operation for the relatively high state starts. Therefore, the time required for the write operation can be shortened as compared with the case where the second control operation is executed in the verify operation of all the program loops.

### 5. Fifth Embodiment

A semiconductor memory device 3 according to a fifth embodiment will be described. In the semiconductor memory device 3 according to the fifth embodiment, the write operation is different from that of the first embodiment. Hereinafter, differences from the first embodiment will be described.

### 5.1 Details of Write Operation

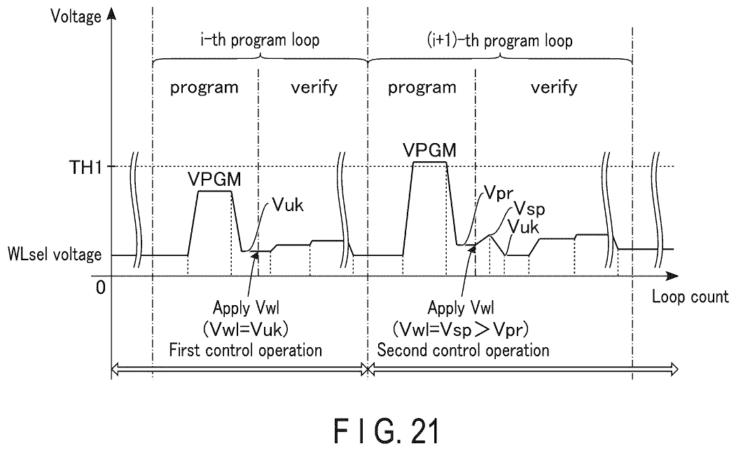

FIG. 21 is a diagram for describing an example of a method of controlling the voltage Vwl applied to the word line WLsel in the write operation of the semiconductor memory device 3 according to the fifth embodiment. FIG. 21 illustrates an example of the waveform of the voltage of the word line WLsel in the write operation of the semiconductor memory device 3 according to the fifth embodiment.

As illustrated in FIG. 21, in an i-th program loop (i is an integer equal to or greater than one), the voltage VPGM is lower than a threshold value TH1. In this case, after the program operation, the sequencer 14 executes the first control operation of applying the voltage Vuk that is a voltage after discharging the voltage of the word line WLsel as the voltage Vwl to the word line WLsel in a case where the voltage VREAD is applied to the word line WLusel. In an (i+1)-th program loop, the voltage VPGM is stepped up from the voltage VPGM in the i-th program loop and is higher than the threshold value TH1. In this case, after the program operation, the sequencer 14 executes the second control operation of discharging the voltage of the word line WLsel to the voltage Vpr, and then applying the voltage Vsp increased from the voltage Vpr to the word line WLsel as the voltage Vwl in a case where the voltage VREAD is applied to the word line WLusel. In a case where there are seven write states of “A” state to “G” state except for “Er” state, for example, the i-th program loop includes “F” state as the write state, and the (i+1)-th program loop includes “G” state as the write state, but is not limited thereto.

As described above, according to the present embodiment, in each program loop, in a case where the voltage VPGM applied during the program operation is less than the threshold value TH1, the sequencer 14 executes the first control operation. That is, after the program operation, the voltage Vwl is set to the voltage Vuk that is a voltage after discharging the voltage of the word line WLsel. On the other hand, in each program loop, in a case where the voltage VPGM applied during the program operation is equal to or greater than the threshold value TH1, the sequencer 14 executes the second control operation. That is, after the program operation, the voltage Vwl is set to the voltage Vsp obtained by discharging the voltage of the word line WLsel to the voltage Vpr and then increasing the voltage Vpr. Thereafter, the voltage Vuk obtained by decreasing the voltage Vsp is applied. The threshold value TH1 is, for example, the voltage VPGM corresponding to a relatively high write state, but is not limited thereto.

The verify initial time period Td in the program loop in which the first control operation is executed is set shorter than the verify initial time period Td in the program loop in which the second control operation is executed.

### 5.2 Effects According to Present Embodiment

According to the present embodiment, the occurrence of GIDL can be suppressed during the write operation as in the first embodiment. Therefore, since the occurrence of HCI can be suppressed, deterioration of the reliability of the memory cell can be suppressed.

In addition, since the first control operation is executed in the verify operation of some program loops, as in the first embodiment, the time required for the write operation can be shortened as compared with the case where the second control operation is executed in the verify operation of all the program loops.

### 6. Sixth Embodiment

A semiconductor memory device 3 according to a sixth embodiment will be described. In the semiconductor memory device 3 according to the sixth embodiment, the write operation is different from that of the first embodiment. Hereinafter, differences from the first embodiment will be described.

### 6.1 Details of Write Operation

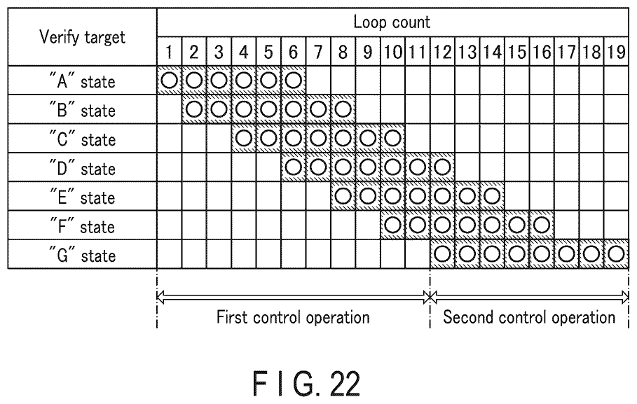

FIG. 22 is a diagram for describing an example of a method of controlling the voltage Vwl applied to the word line WLsel in the write operation of the semiconductor memory device 3 according to the sixth embodiment. FIG. 22 illustrates an example of settings of the program loops of FIG. 10 illustrated in the first embodiment.

As illustrated in FIG. 22, “G” state is set as a verify target from the 12th program loop. Before the program loop of “G” state starts, the sequencer 14 executes the first control operation of applying the voltage Vuk that is a voltage after discharging the voltage of the word line WLsel as the voltage Vwl to the word line WLsel in a case where the voltage VREAD is applied to the word line WLusel after the program operation. After the program loop of “G” state starts, the sequencer 14 executes the second control operation of discharging the voltage of the word line WLsel to the voltage Vpr after the program operation, and then applying the voltage Vsp obtained by increasing the voltage Vpr as the voltage Vwl to the word line WLsel in a case where the voltage VREAD is applied to the word line WLusel.

As described above, according to the present embodiment, in a case where the write state has not reached the target state in each program loop, the sequencer 14 executes the first control operation. That is, after the program operation, the voltage Vwl is set to the voltage Vuk that is a voltage after discharging the voltage of the word line WLsel. On the other hand, in each program loop, in a case where the write state reaches the target state, the sequencer 14 executes the second control operation. That is, after the program operation, the voltage Vwl is set to the voltage Vsp obtained by discharging the voltage of the word line WLsel to the voltage Vpr and then increasing the voltage Vpr. Thereafter, the voltage Vuk obtained by decreasing the voltage Vsp is applied. The target state is, for example, a relatively high write state, but is not limited thereto.

The verify initial time period Td in the program loop in which the first control operation is executed is set shorter than the verify initial time period Td in the program loop in which the second control operation is executed.

### 6.2 Effects According to Present Embodiment

According to the present embodiment, the occurrence of GIDL can be suppressed during the write operation as in the first embodiment. Therefore, since the occurrence of HCI can be suppressed, deterioration of the reliability of the memory cell can be suppressed.

In addition, since the first control operation is executed in the verify operation of some program loops, as in the first embodiment, the time required for the write operation can be shortened as compared with the case where the second control operation is executed in the verify operation of all the program loops.

Furthermore, even in a case where the same voltage VPGM is applied to each word line WL, the threshold voltage Vth of the memory cells connected to the word line WL varies for each word line WL. In other words, the ease of writing differs for each word line WL. The semiconductor memory device 3 holds, for example, information (hereinafter, referred to as “state information”) indicating to which write state the memory cells connected to the word line WLsel are written. According to the present embodiment, in the write operation, execution of the first control operation or the second control operation is controlled in units of write states based on the state information in each program loop. Therefore, according to the present embodiment, variations in the ease of writing for each word line WL can be suppressed.

### 7. Seventh Embodiment

A semiconductor memory device 3 according to a seventh embodiment will be described. In the semiconductor memory device 3 according to the seventh embodiment, the configuration of the sequencer 14 and the circuit configuration of the driver module 15 are different from those of the first embodiment. Hereinafter, differences from the first embodiment will be described.

### 7.1 Configuration of Semiconductor Memory Device

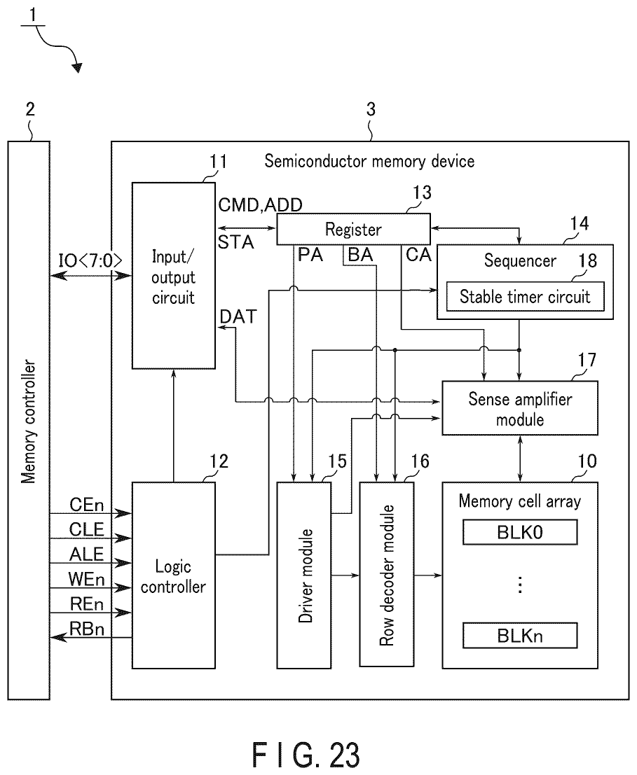

A configuration of the semiconductor memory device 3 will be described with reference to FIG. 23. FIG. 23 is a block diagram illustrating an example of a configuration of the memory system 1 including the semiconductor memory device according to the seventh embodiment.

The sequencer 14 of the semiconductor memory device 3 includes a stable timer circuit 18. The stable timer circuit 18 is a circuit that measures a time period (hereinafter, described as “stable time period Tb”) taken from when a voltage is applied to a bit line BL until the voltage of the bit line BL is stabilized. The stable time period Tb is a time period from when the voltage of the word line WLsel transitions to the verify voltage VCGRV until sensing is performed. The sequencer 14 controls, for example, the verify initial time period Td measured by discharge timer circuits 56 and 57, the underkick voltage Vuk supplied from the charge pump circuit 53, and the stable time period Tb of the voltage of the bit line BL measured by the stable timer circuit 18.

### 7.2 Circuit Configuration of Driver Module

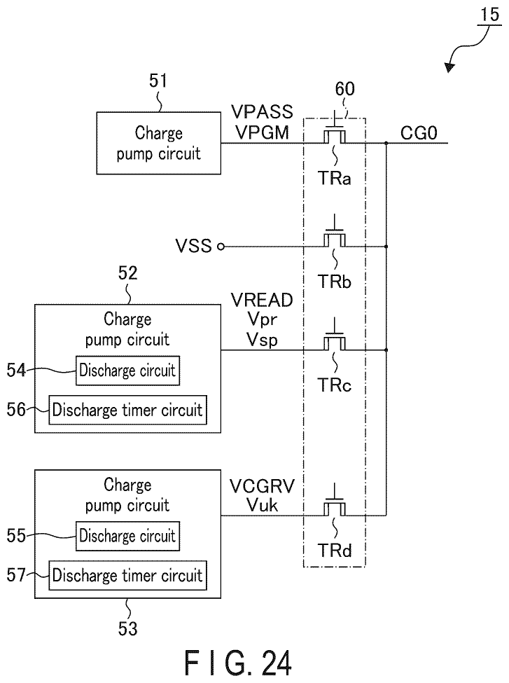

The circuit configuration of the driver module 15 will be described with reference to FIG. 24. FIG. 24 is a circuit diagram illustrating an example of the circuit configuration of the driver module 15. FIG. 24 illustrates a configuration in which a voltage is applied to the signal line CG0 in the driver module 15. The configuration for applying a voltage to the other signal lines CG is also similar to that in FIG. 24. As illustrated in FIG. 24, the driver module 15 includes charge pump circuits 51, 52, and 53, and a CG select driver 60.

The circuit configurations of the charge pump circuit 51 and the CG select driver 60 are similar to those in FIG. 8 in the first embodiment.

The charge pump circuit 52 includes the discharge circuit 54 and the discharge timer circuit 56. The configuration of the discharge circuit 54 is similar to that of FIG. 8 illustrated in the first embodiment. The discharge timer circuit 56 is a circuit that measures the verify initial time period Td.

The charge pump circuit 53 includes the discharge circuit 55 and the discharge timer circuit 57. The configuration of the discharge circuit 55 is similar to that of FIG. 8 in the first embodiment. The discharge timer circuit 57 is a circuit that measures the verify initial time period Td.

### 7.3 Details of Write Operation

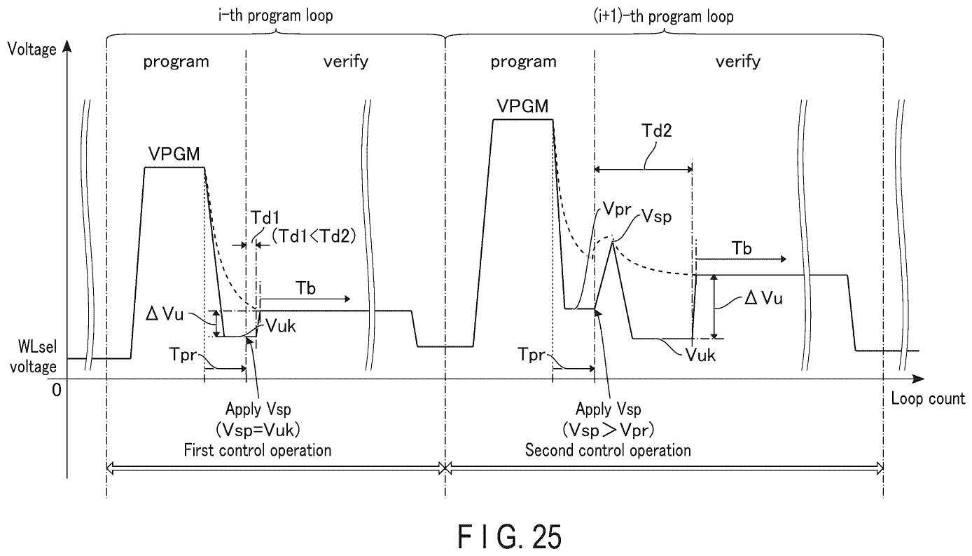

FIG. 25 is a diagram for describing an example of a method of controlling the verify initial time period Td in the write operation of the semiconductor memory device 3 according to the seventh embodiment. FIG. 25 illustrates an example of the waveform of the voltage of the word line WLsel in the write operation of the semiconductor memory device 3 according to the seventh embodiment. In FIG. 25, regarding the voltage of the word line WLsel, the voltage at the near end (Near) is indicated by the solid line, and the voltage at the far end (Far) is indicated by the broken line. In addition, a case where the first control operation is executed in the i-th program loop (i is an integer equal to or greater than one) and the second control operation is executed in the (i+1)-th program loop is illustrated.

In each program loop, after the discharge timer circuit 56 or 57 measures the predetermined verify initial time period Td, the stable timer circuit 18 waits for the stable time until the voltage of the bit line BL is stabilized. Thereafter, the sense amplifier unit SAU senses the data stored in the memory cell transistor MTsel based on the magnitude of the voltage of the bit line BL.

As illustrated in FIG. 25, in the i-th program loop, the sequencer 14 sets the verify initial time period Td measured by the discharge timer circuit 57 to the verify initial time period Td1. In this case, after the program operation, the sequencer 14 executes the first control operation of applying the voltage Vuk that is a voltage after discharging the voltage of the word line WLsel as the voltage Vwl to the word line WLsel in a case where the voltage VREAD is applied to the word line WLusel. In the (i+1)-th program loop, the sequencer 14 sets the verify initial time period Td measured by the discharge timer circuit 56 to the verify initial time period Td2. In this case, after the program operation, the sequencer 14 executes the second control operation of discharging the voltage of the word line WLsel to the voltage Vpr, and then applying the voltage Vsp increased from the voltage Vpr to the word line WLsel as the voltage Vwl in a case where the voltage VREAD is applied to the word line WLusel. Thereafter, the voltage Vuk obtained by decreasing the voltage Vsp is applied. The verify initial time period Td1 in the program loop in which the first control operation is performed is set to be shorter than the verify initial time period Td2 in the program loop in which the second control operation is performed. In a case where there are seven write states of “A” state to “G” state except for “Er” state, for example, the i-th program loop includes “F” state as the write state, and the (i+1)-th program loop includes “G” state as the write state, but is not limited thereto.

As described above, according to the present embodiment, the verify initial time period Td in the program loop in which the first control operation is performed is controlled to be shorter than that in the program loop in which the second control operation is performed.

### 7.4 Effects According to Present Embodiment

According to the present embodiment, the occurrence of GIDL can be suppressed during the write operation as in the first embodiment. Therefore, since the occurrence of HCI can be suppressed, deterioration of the reliability of the memory cell can be suppressed.

In addition, since the first control operation is executed in the verify operation of some program loops, as in the first embodiment, the time required for the write operation can be shortened as compared with the case where the second control operation is executed in the verify operation of all the program loops.

In the program loop in which the first control operation is performed, in a case where the verify initial time period Td is relatively long, the timing at which the voltage at the far end (Far) of the word line WLsel converges to the verify voltage may be later than the timing at which the voltage at the near end (Near) of the word line WLsel converges to the verify voltage due to the application of the underkick voltage Vuk and the verify voltage.

In addition, in a case where the verify initial time period Td is relatively short in the program loop in which the second control operation is performed, the timing at which the voltage at the far end (Far) of the word line WLsel converges to the verify voltage may be later than the timing at which the voltage at the near end (Near) of the word line WLsel converges to the verify voltage due to the application of the recovery voltage Vpr, the voltage Vsp, the underkick voltage Vuk, and the verify voltage.

As described above, in a case where the timing at which the voltage of the word line WLsel converges to the verify voltage is shifted between the near end (Near) and the far end (Far), sensing after the voltage of the bit line BL is stabilized may not be performed at an appropriate timing. In this case, the threshold voltage distribution of the memory cell transistor MTsel is widened, leading to a decrease in the reliability of the memory cell.

According to the present embodiment, the verify initial time period Td measured by the discharge timer circuit 56 in the first control operation is set to the verify initial time period Td1, and the verify initial time period Td measured by the discharge timer circuit 57 in the second control operation is set to the verify initial time period Td2 (>Td1). As a result, it is possible to suppress the above-described timing deviation in each of the program loop in which the first control operation is performed and the program loop in which the second control operation is performed. Therefore, since sensing is performed at an appropriate timing, deterioration of reliability of the memory cell can be suppressed.

### 7.5 First Modification

A semiconductor memory device 3 according to a first modification of the seventh embodiment will be described. In the semiconductor memory device 3 according to the present modification, the write operation is different from that of the seventh embodiment. Hereinafter, differences from the seventh embodiment will be described.

### 7.5.1 Details of Write Operation

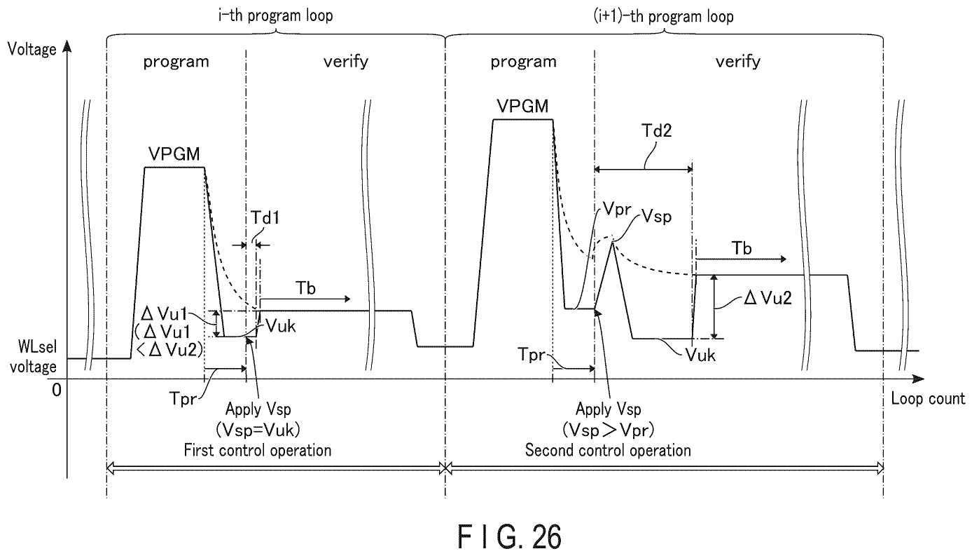

FIG. 26 is a diagram for describing an example of a method of controlling the underkick voltage Vuk in the write operation of the semiconductor memory device 3 according to the first modification of the seventh embodiment. FIG. 26 illustrates an example of the waveform of the voltage of the word line WLsel in the write operation of the semiconductor memory device 3 according to the present modification. In FIG. 26, regarding the voltage of the word line WLsel, the voltage at the near end (Near) is indicated by the solid line, and the voltage at the far end (Far) is indicated by the broken line. In addition, a case where the first control operation is executed in the i-th program loop (i is an integer equal to or greater than one) and the second control operation is executed in the (i+1)-th program loop is illustrated.

As illustrated in FIG. 26, in the i-th program loop, the sequencer 14 sets the underkick voltage Vuk such that a voltage difference ΔVu between the voltage Vuk and the verify voltage becomes ΔVu1. In this case, after the program operation, the sequencer 14 executes a first control operation of applying the voltage Vuk that is a voltage after discharging the voltage of the word line WLsel as the voltage Vwl to the word line WLsel in a case where a voltage VREAD is applied to the word line WLusel. In the (i+1)-th program loop, the sequencer 14 sets the underkick voltage Vuk such that the voltage difference ΔVu between the voltage Vuk and the verify voltage becomes ΔVu2. In this case, after the program operation, the sequencer 14 executes the second control operation of discharging the voltage of the word line WLsel to the voltage Vpr, and then applying the voltage Vsp increased from the voltage Vpr to the word line WLsel as the voltage Vwl in a case where the voltage VREAD is applied to the word line WLusel. Thereafter, the voltage Vuk obtained by decreasing the voltage Vsp is applied. The underkick voltage Vuk in the program loop in which the first control operation is performed and the underkick voltage Vuk in the program loop in which the second control operation is performed are set such that the voltage difference ΔVu1 in the program loop in which the first control operation is performed is smaller than the voltage difference ΔVu2 in the program loop in which the second control operation is performed.

As described above, according to the present embodiment, the voltage difference ΔVu between the voltage Vuk and the verify voltage in the program loop in which the first control operation is performed is controlled to be smaller than that in the program loop in which the second control operation is performed.

### 7.5.2 Effects According to Present Modification

In the program loop in which the first control operation is performed, in a case where the voltage difference ΔVu is relatively large, the timing at which the voltage at the far end (Far) of the word line WLsel converges to the verify voltage may be later than the timing at which the voltage at the near end (Near) of the word line WLsel converges to the verify voltage due to the application of the underkick voltage Vuk and the verify voltage.

In the program loop in which the second control operation is performed, in a case where the voltage difference ΔVu is relatively small, the timing at which the voltage at the far end (Far) of the word line WLsel converges to the verify voltage may be later than the timing at which the voltage at the near end (Near) of the word line WLsel converges to the verify voltage due to the application of the recovery voltage Vpr, the voltage Vsp, the underkick voltage Vuk, and the verify voltage.

In the present modification, the underkick voltage Vuk supplied from the charge pump circuit 53 in the first control operation is set such that the voltage difference ΔVu becomes ΔVu1, and the underkick voltage Vuk supplied from the charge pump circuit 53 in the second control operation is set such that the voltage difference ΔVu becomes ΔVu2 (>ΔVu1). As a result, it is possible to suppress the above-described timing deviation in each of the program loop in which the first control operation is performed and the program loop in which the second control operation is performed. Therefore, since sensing is performed at an appropriate timing, deterioration of reliability of the memory cell can be suppressed.

### 7.6 Second Modification

A semiconductor memory device 3 according to a second modification of the seventh embodiment will be described. In the semiconductor memory device 3 according to the present modification, the write operation is different from that of the seventh embodiment. Hereinafter, differences from the seventh embodiment will be described.

### 7.6.1 Details of Write Operation

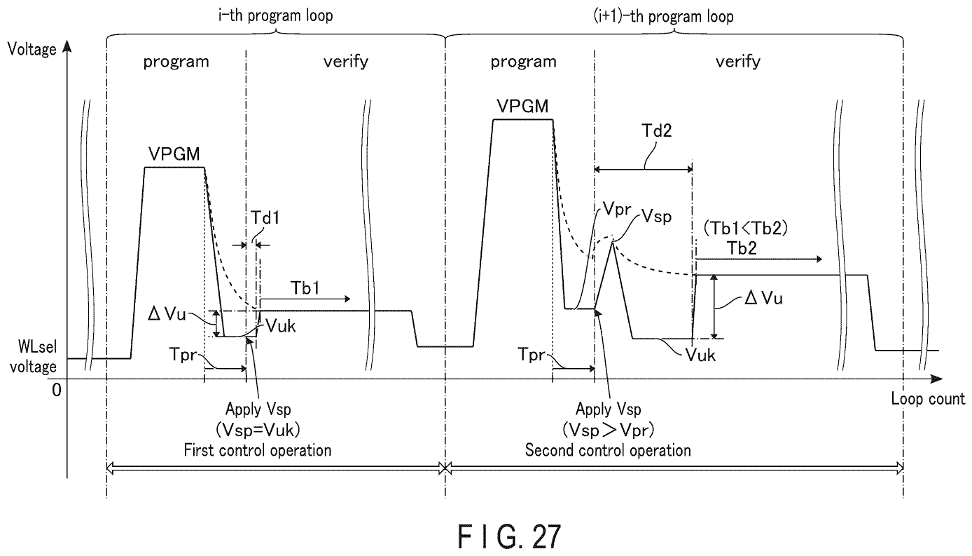

FIG. 27 is a diagram for describing an example of a method of controlling the voltage stable time period Tb of the bit line BL in the write operation of the semiconductor memory device 3 according to the second modification of the seventh embodiment. FIG. 27 illustrates an example of the waveform of the voltage of the word line WLsel in the write operation of the semiconductor memory device 3 according to the present modification. In FIG. 27, regarding the voltage of the word line WLsel, the voltage at the near end (Near) is indicated by the solid line, and the voltage at the far end (Far) is indicated by the broken line. In addition, a case where the first control operation is executed in the i-th program loop (i is an integer equal to or greater than one) and the second control operation is executed in the (i+1)-th program loop is illustrated.

As illustrated in FIG. 27, in the i-th program loop, the sequencer 14 sets the stable time period Tb of the bit line BL measured by the stable timer circuit 18 to a stable time period Tb1. In this case, after the program operation, the sequencer 14 executes the first control operation of applying the voltage Vuk that is a voltage after discharging the voltage of the word line WLsel as the voltage Vwl to the word line WLsel in a case where the voltage VREAD is applied to the word line WLusel. In the (i+1)-th program loop, the sequencer 14 sets the stable time period Tb of the bit line BL measured by the stable timer circuit 18 to a stable time period Tb2. In this case, after the program operation, the sequencer 14 executes the second control operation of discharging the voltage of the word line WLsel to the voltage Vpr, and then applying the voltage Vsp increased from the voltage Vpr to the word line WLsel as the voltage Vwl in a case where the voltage VREAD is applied to the word line WLusel. Thereafter, the voltage Vuk obtained by decreasing the voltage Vsp is applied. The stable time period Tb1 is controlled so as to eliminate the above-described timing deviation in the program loop in which the first control operation is performed. The stable time period Tb2 is controlled so as to eliminate the above-described timing deviation in the program loop in which the second control operation is performed. The stable time period Tb2 tends to require a relatively long stable time period Tb under the influence of discharge from the voltage Vsp of the voltage of the word line WLsel. Therefore, for example, the stable time period Tb2 in the program loop in which the second control operation is performed is set to be longer than the stable time period Tb1 in the program loop in which the first control operation is performed.

### 7.6.2 Effects According to Present Modification

In the present modification, the stable time period Tb of the bit line BL measured by the stable timer circuit 18 in the first control operation is set to the stable time period Tb1, and the stable time period Tb of the bit line BL measured by the stable timer circuit 18 in the second control operation is set to the stable time period Tb2. The stable time period Tb1 is controlled so as to eliminate the above-described timing deviation in the program loop in which the first control operation is performed. The stable time period Tb2 is controlled so as to eliminate the above-described timing deviation in the program loop in which the second control operation is performed. As a result, in each of the program loop in which the first control operation is performed and the program loop in which the second control operation is performed, the above-described difference in timing can be adjusted by the stable time period Tb. Therefore, since sensing is performed at an appropriate timing, deterioration of reliability of the memory cell can be suppressed.

### 8. Others

As described above, a semiconductor memory device (3) according to the embodiments includes a first word line (WL), a second word line (WL), a first memory cell (MT) connected to the first word line (WL), a second memory cell (MT) connected to the second word line (WL), and a control circuit (14) configured to perform a data write operation to the first memory cell and the second memory cell. In the write operation, a plurality of program loops each including a program operation and a verify operation are sequentially executed. In the verify operation for a first memory cell (MTsel), the control circuit (14) applies a second voltage (Vsp) to a first word line (WLsel) in a case of applying a first voltage (VREAD) to a second word line (WLusel), and then applies a third voltage (VCGRV) according to a write state to the first word line (WLsel) to change a voltage level of the second voltage (Vsp) according to the progress of the program loops.

Note that the embodiments are not limited to the above-described manner, and various modifications are possible.

The above embodiments and modifications may be combined to the extent possible. For example, each of the second to sixth embodiments may be combined with the seventh embodiment, may be combined with the first modification of the seventh embodiment, or may be combined with the second modification of the seventh embodiment.

In the second modification of the seventh embodiment, an example in which the above-described timing deviation is adjusted by the stable time period Tb of the bit line BL has been described, but the above-described timing deviation may be adjusted by the sense time.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first word line;
a second word line;
a first memory cell connected to the first word line;
a second memory cell connected to the second word line; and
a control circuit configured to perform data write operation to the first memory cell and the second memory cell, wherein
in the write operation, a plurality of program loops each including a program operation and a verify operation are sequentially executed, and
in the verify operation for the first memory cell, the control circuit applies a second voltage to the first word line in a case of applying a first voltage to the second word line, and then applies a third voltage according to a write state to the first word line to change a voltage level of the second voltage according to progress of the program loops.

2. The device according to claim 1, wherein
the program loops include a first loop, a second loop after the first loop, and a third loop after the second loop,
in the first loop, after the program operation, the second voltage is set to a fourth voltage that is a voltage after discharging the voltage of the first word line, and
in each of the second loop and the third loop, after the program operation, the second voltage is set to a sixth voltage obtained by discharging the voltage of the first word line to a fifth voltage and then increasing the fifth voltage.

3. The device according to claim 2, wherein
the second voltage in the second loop is higher than the second voltage in the first loop, and
the second voltage in the third loop is higher than the second voltage in the second loop.

4. The device according to claim 1, wherein
the program loops include a first loop, a second loop after the first loop, and a third loop after the second loop,
in each of the first loop and the second loop, after the program operation, the second voltage is set to a fourth voltage that is a voltage after discharging the voltage of the first word line, and
in the third loop, after the program operation, the second voltage is set to a sixth voltage obtained by discharging the voltage of the first word line to a fifth voltage and then increasing the fifth voltage.

5. The device according to claim 4, wherein
the second voltage in the third loop is higher than the second voltage in the first loop and the second voltage in the second loop.

6. The device according to claim 5, wherein
the second voltage in the second loop is same as the second voltage in the first loop.

7. The device according to claim 1, wherein
the program loops include a first loop, a second loop after the first loop, and a third loop after the second loop,
in each of the second loop and the third loop, after the program operation, the second voltage is set to a fourth voltage that is a voltage after discharging the voltage of the first word line, and
in the first loop, after the program operation, the second voltage is set to a sixth voltage obtained by discharging the voltage of the first word line to a fifth voltage and then increasing the fifth voltage.

8. The device according to claim 7, wherein
the second voltage in the first loop is higher than the second voltage in the second loop and the second voltage in the third loop.

9. The device according to claim 8, wherein
in each of the second loop and the third loop, the second voltage is higher than the third voltage.

10. The device according to claim 1, wherein
the program loops include a first loop, a second loop after the first loop, and a third loop after the second loop,
in the second loop, after the program operation, the second voltage is set to a fourth voltage that is a voltage after discharging the voltage of the first word line, and
in each of the first loop and the third loop, after the program operation, the second voltage is set to a sixth voltage obtained by discharging the voltage of the first word line to a fifth voltage and then increasing the fifth voltage.

11. The device according to claim 10, wherein
the second voltage in the first loop and the second voltage in the third loop are higher than the second voltage in the second loop.

12. The device according to claim 11, wherein
in the second loop, the second voltage is higher than the third voltage.

13. The device according to claim 1, wherein
in each of the program loops, in a case where a seventh voltage applied during the program operation is less than a first threshold value, the second voltage is set to a fourth voltage that is a voltage after discharging the voltage of the first word line after the program operation, and in a case where the seventh voltage is equal to or greater than the first threshold value, the second voltage is set to a sixth voltage obtained by discharging the voltage of the first word line to a fifth voltage and then increasing the fifth voltage after the program operation.

14. The device according to claim 1, wherein
in each of the program loops, in a case where the write state does not reach a target state, the second voltage is set to a fourth voltage that is a voltage after discharging the voltage of the first word line after the program operation, and in a case where the write state reaches the target state, the second voltage is set to a sixth voltage obtained by discharging the voltage of the first word line to a fifth voltage and then increasing the fifth voltage after the program operation.

15. The device according to claim 1, further comprising
a first timer circuit configured to measure a first time period from a start of the verify operation for the first memory cell until an application of the third voltage to the first word line, wherein
the program loops include a first loop and a second loop,
in the first loop, after the program operation, the second voltage is set to a fourth voltage that is a voltage after discharging the voltage of the first word line,
in the second loop, after the program operation, the second voltage is set to a sixth voltage obtained by discharging the voltage of the first word line to a fifth voltage and then increasing the fifth voltage, and
the control circuit controls the first time period.

16. The device according to claim 15, wherein
in the first loop, the first time period is set to a second time period,
in the second loop, the first time period is set to a third time period, and
the second time period is shorter than the third time period.

17. The device according to claim 1, wherein
the program loops include a first loop and a second loop,
in the first loop, after the program operation, the second voltage is set to a fourth voltage that is a voltage after discharging the voltage of the first word line,
in the second loop, after the program operation, the second voltage is set to a sixth voltage obtained by discharging the voltage of the first word line to a fifth voltage and then increasing the fifth voltage, and then the second voltage is set to a seventh voltage obtained by decreasing the sixth voltage, and
the control circuit controls the fourth voltage and the seventh voltage.

18. The device according to claim 17, wherein
the fourth voltage and the seventh voltage are set such that a potential difference between the fourth voltage and the third voltage in the first loop is smaller than a potential difference between the seventh voltage and the third voltage in the second loop.

19. The device according to claim 1, further comprising:
a first bit line connected to the first memory cell and the second memory cell; and
a first timer circuit configured to measure a stable time of a voltage of the first bit line, wherein
the program loops include a first loop and a second loop,
in the first loop, after the program operation, the second voltage is set to a fourth voltage that is a voltage after discharging the voltage of the first word line,
in the second loop, after the program operation, the second voltage is set to a sixth voltage obtained by discharging the voltage of the first word line to a fifth voltage and then increasing the fifth voltage, and then the second voltage is set to a seventh voltage obtained by decreasing the sixth voltage, and
the control circuit applies the voltage to the first bit line and controls the stable time in the verify operation for the first memory cell.

20. The device according to claim 1, wherein
the semiconductor memory device is a NAND flash memory.
